(19) United States
(12) Patent Application Publication
(10) Pub. No.: US 2025/0220895 A1
(43) Pub. Date: Jul. 3, 2025

(54) SEMICONDUCTOR MEMORY DEVICE

(71) Applicant: Samsung Electronics Co., Ltd., Suwon-si (KR)

(72) Inventors: Changyoung LEE, Suwon-si (KR); YOUNG SEOK PARK, Suwon-si (KR); ChangSik YOO, Suwon-si (KR); HYUN-CHUL YOON, Suwon-si (KR); JEONGDON IHM, Suwon-si (KR); SANG-HOON JUNG, Suwon-si (KR)

(21) Appl. No.: 18/927,887

(22) Filed: Oct. 26, 2024

(30) Foreign Application Priority Data
Jan. 3, 2024 (KR) 10-2024-0001162

(51) Int. Cl. H10B 12/00; H01L 23/00; H01L 25/065; H01L 25/18; H10B 80/00

(52) U.S. Cl. CPC H10B 12/50; H01L 24/08; H01L 25/0657; H01L 25/18; H10B 12/315; H10B 80/00; H01L 2224/08145; H01L 2924/1431; H01L 2924/1436

(57) ABSTRACT

A semiconductor memory device with a cell over periphery (COP) structure, which includes a first semiconductor structure, and a second semiconductor structure disposed on a lower side of the first semiconductor structure. The first semiconductor structure includes a memory region, a first region, a memory cell array disposed in the memory region and including vertical channel transistors, and first peripheral circuits disposed in the first region and including vertical channel transistors or horizontal channel transistors. The second semiconductor structure includes a second region, a third region, second peripheral circuits disposed in the second region, which is on a lower side of the first region, and including horizontal channel transistors, and third peripheral circuits disposed in the third region, which is on a lower side of the memory region, and including horizontal channel transistors.

### CROSS-REFERENCE TO RELATED APPLICATION(S)

This application claims priority under 35 U.S.C. § 119 to Korean Patent Application No. 10-2024-0001162 filed on Jan. 3, 2024, in the Korean Intellectual Property Office, the disclosure of which is incorporated by reference herein in its entirety.

### BACKGROUND

Embodiments of the present disclosure described herein relate to a semiconductor device, and more particularly, relate to a semiconductor memory device.

Semiconductor memory devices may be classified as volatile memory devices or nonvolatile memory devices. A volatile memory device may retain data stored therein while a power is supplied, and a nonvolatile memory device may retain data stored therein even though a power is turned off. The volatile memory device provides a fast speed, and the nonvolatile memory device provides excellent safety and endurance.

To increase the storage capacity of the semiconductor memory device and to make the degree of integration of the semiconductor memory device higher, a cell over periphery (COP) structure may provide memory cells that are arranged three-dimensionally instead of two-dimensionally and peripheral circuits for the memory cells are disposed under the memory cells.

### SUMMARY

Embodiments of the present disclosure provide a semiconductor memory device optimizing a chip size by appropriately disposing peripheral circuits in the semiconductor memory device.

According to an embodiment, a semiconductor memory device with a cell over periphery (COP) structure includes a first semiconductor structure, and a second semiconductor structure disposed on a lower side of the first semiconductor structure. The first semiconductor structure includes a memory region, a first region, a memory cell array disposed in the memory region and including vertical channel transistors (VCTs), and first peripheral circuits disposed in the first region and including VCTs or horizontal channel transistors (HCTs). The second semiconductor structure includes a second region, a third region, second peripheral circuits disposed in the second region, which is on a lower side of the first region, and including HCTs, and third peripheral circuits disposed in the third region, which is on a lower side of the memory region, and including HCTs.

According to an embodiment, a semiconductor memory device with a cell over periphery (COP) structure includes a first semiconductor structure, and a second semiconductor structure disposed on a lower side of the first semiconductor structure. The first semiconductor structure includes a memory region, a first region, a memory cell array including a plurality of first and second sub-memory cell arrays disposed in the memory region and implemented by using vertical channel transistors (VCTs), and first peripheral circuits disposed in the first region and implemented by using VCTs or horizontal channel transistors (HCTs). The second semiconductor structure includes a second region, a third region, second peripheral circuits disposed in the second region, which is on a lower side of the first region, and third peripheral circuits disposed in the third region, which is on a lower side of the memory region.

According to an embodiment, a semiconductor memory device with a cell over periphery (COP) structure includes a first semiconductor structure, and a second semiconductor structure disposed on a lower side of the first semiconductor structure. The first semiconductor structure includes a memory region, a first region, a memory cell array disposed in the memory region and including vertical channel transistors (VCTs), and first peripheral circuits disposed in the first region, including VCTs or horizontal channel transistors, and having first timing margins associated with an operation of the semiconductor memory device. The second semiconductor structure includes a second region, second peripheral circuits disposed in the second region, which is on a lower side of the first region, and having second timing margins associated with an operation of the semiconductor memory device. The first timing margins are greater than the second timing margins.

### BRIEF DESCRIPTION OF THE FIGURES

The above and other objects and features of the present disclosure will become apparent by describing in detail embodiments thereof with reference to the accompanying drawings.

FIG. 1 is a perspective view illustrating a semiconductor memory device according to an embodiment of the present disclosure.

FIG. 2 is a block diagram illustrating a memory system including a semiconductor

memory device according to embodiments of the present disclosure.

FIG. 3 is a block diagram illustrating an embodiment of the semiconductor memory device of FIG. 1 according to example embodiments.

FIG. 4A is a cross-sectional view of the semiconductor memory device taken along line X-X′ of FIG. 1 according to example embodiments.

FIG. 4B is a diagram for describing a memory cell array and peripheral circuits disposed in regions of FIG. 4A according to example embodiments.

FIG. 4C is a graph for describing characteristics of first peripheral circuits and second peripheral circuits disposed in regions of FIG. 4A according to example embodiments.

FIG. 5A is a cross-sectional view of the semiconductor memory device taken along line X-X′ of FIG. 1 according to example embodiments.

FIG. 5B is a diagram for describing a memory cell array and peripheral circuits disposed in regions of FIG. 5A according to example embodiments.

FIG. 6A is a cross-sectional view of the semiconductor memory device taken along line X-X′ of FIG. 1 according to example embodiments.

FIG. 6B is a diagram for describing a memory cell array and peripheral circuits disposed in regions of FIG. 6A according to example embodiments.

FIG. 7A is a cross-sectional view of the semiconductor memory device taken along line X-X′ of FIG. 1 according to example embodiments.

FIG. 7B is a diagram for describing a memory cell array and peripheral circuits disposed in regions of FIG. 7A according to example embodiments.

FIG. 8A is a cross-sectional view of the semiconductor memory device taken along line X-X′ of FIG. 1 according to example embodiments.

FIG. 8B is a diagram for describing a memory cell array and peripheral circuits disposed in regions of FIG. 8A according to example embodiments.

FIG. 9 is a plan view for describing a first semiconductor structure of FIG. 1 according to example embodiments.

FIG. 10 is a plan view for describing the second semiconductor structure of FIG. 1 according to example embodiments.

FIGS. 11A and 11B are diagrams for describing the reduction of a chip size by a semiconductor memory device according to an embodiment of the present disclosure.

FIG. 12 is a diagram illustrating a portion of the semiconductor memory device of FIG. 1 according to example embodiments.

FIG. 13A is a diagram for describing a plurality of sub-memory cell arrays disposed in a memory region of the semiconductor memory device of FIG. 1 according to example embodiments.

FIG. 13B is a diagram for describing a peripheral circuits disposed on lower sides of the plurality of sub-memory cell arrays of FIG. 13A according to example embodiments.

FIG. 14 is a diagram illustrating a semiconductor memory device according to embodiments of the present disclosure.

FIG. 15 is a plan view illustrating a pad array included in the semiconductor memory device of FIG. 14 according to example embodiments.

FIG. 16A is a cross-sectional view of the semiconductor memory device of FIG. 14 taken along line A-A′ of FIG. 15 according to example embodiments.

FIG. 16B is a cross-sectional view of the semiconductor memory device of FIG. 14 taken along line B-B′ of FIG. 15 according to example embodiments.

### DETAILED DESCRIPTION

Below, embodiments of the present disclosure will be described in detail and clearly to such an extent that one skilled in the art easily carries out the present disclosure.

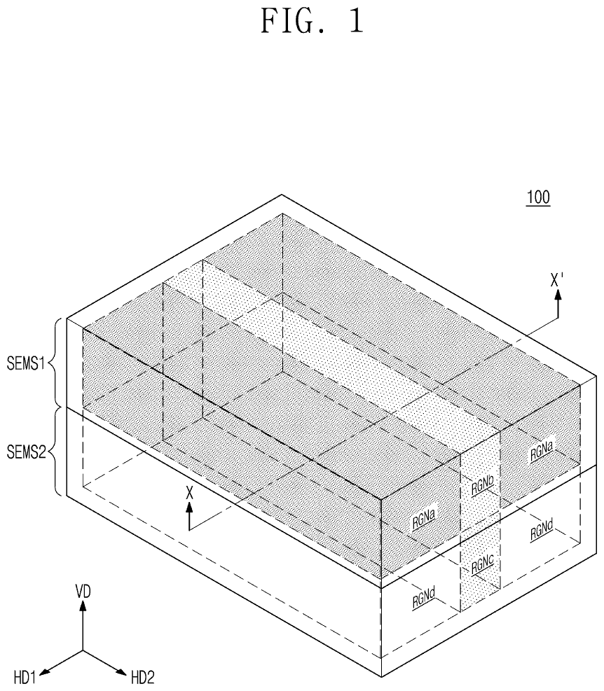

FIG. 1 is a perspective view illustrating a semiconductor memory device according to an embodiment of the present disclosure.

Referring to FIG. 1, a semiconductor memory device 100 may include a first semiconductor structure SEMS1 and a second semiconductor structure SEMS2. In an embodiment, the second semiconductor structure SEMS2 may be disposed under the first semiconductor structure SEMS1 is illustrated in FIG. 1, but this is only an example. In another embodiment, the first semiconductor structure SEMS1 may be disposed under the second semiconductor structure SEMS2. In an embodiment, the first semiconductor structure SEMS1 may be formed from a first semiconductor wafer and the second semiconductor structure SEMS2 may be formed from a second semiconductor wafer different from the first semiconductor wafer. The semiconductor memory device 100 may include a dynamic random access memory (DRAM), a double data rate 4 (DDR4) synchronous DRAM (SDRAM), a low power DDR4 (LPDDR4) SDRAM, an LPDDR5 SDRAM, a graphics double data rate5 (GDDR5) SDRAM, a GDDR6 SDRAM, a high bandwidth memory 2 (HBM2), an HBM2E, or an HBM3, but the present invention is not limited thereto.

In an embodiment, the semiconductor memory device 100 may have a cell over periphery (COP) structure in which peripheral circuits are disposed under memory cells. As the COP structure is applied to the semiconductor memory device 100, the storage capacity of the semiconductor memory device 100 may increase, and the degree of integration of the semiconductor memory device 100 may become higher, the utilization of space may be improved, and the costs for manufacturing may be reduced.

The semiconductor memory device 100 may include a memory cell array and peripheral circuits associated with the memory cell array. For example, the memory cell array may include a plurality of memory cells for storing data, and the peripheral circuits may include a plurality of circuits for writing, reading, and managing data of the memory cells.

The semiconductor memory device 100 may include regions RGNa, RGNb, RGNc, and RGNd therein. Each of the regions RGNa and RGNb may be a region in the first semiconductor structure SEMS1, and each of the regions RGNc and RGNd may be a region in the second semiconductor structure SEMS2.

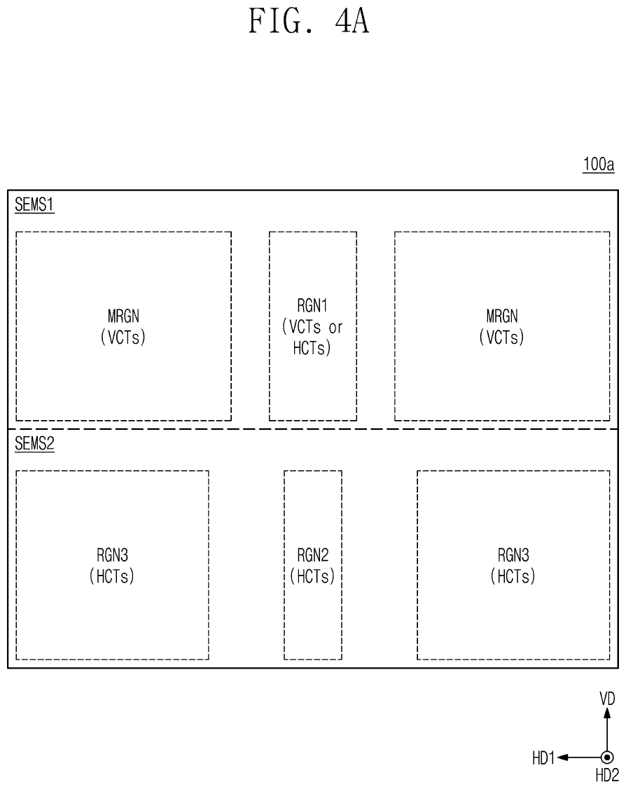

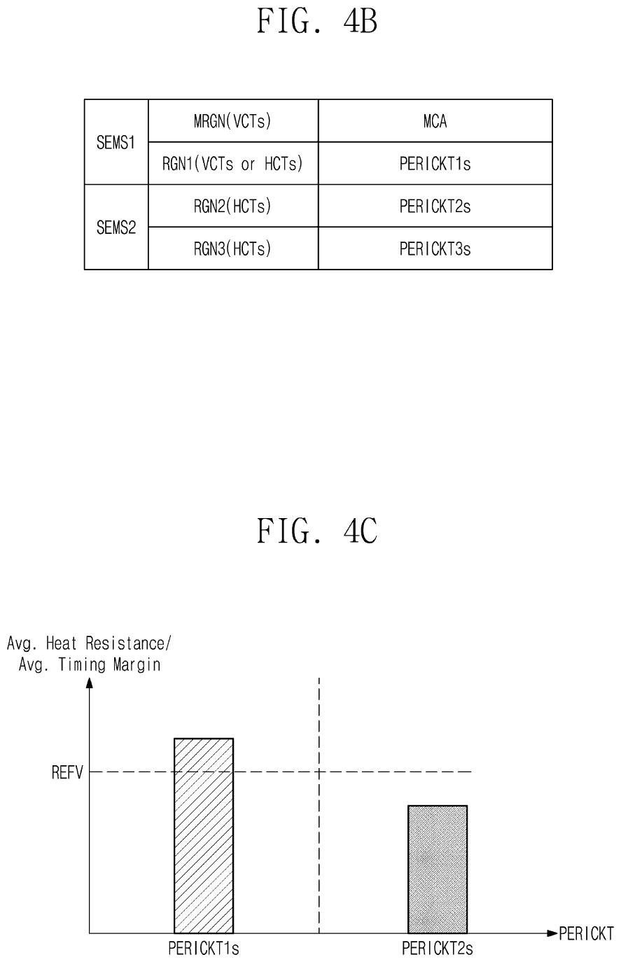

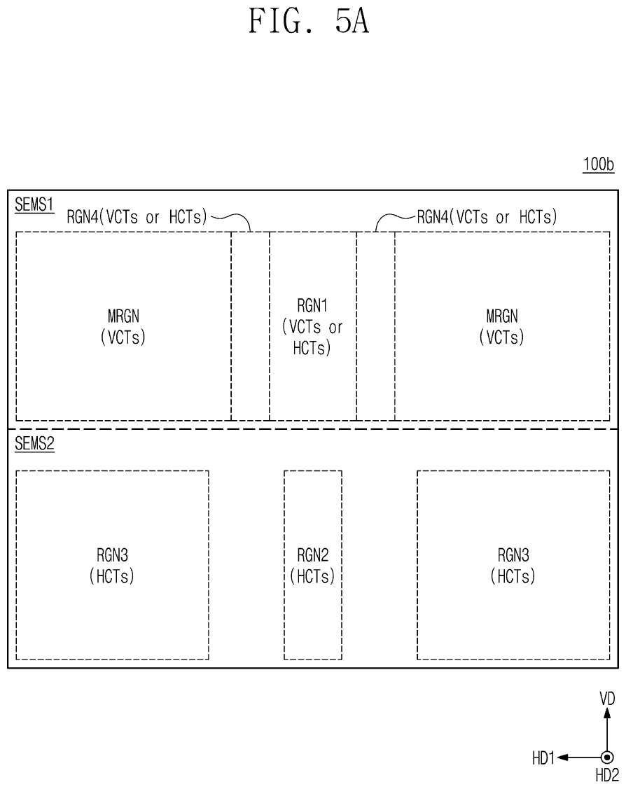

In an embodiment, each of the regions RGNa, RGNb, RGNc, and RGNd may include one or more regions as illustrated in FIG. 1 (e.g., the region RGNa may include two regions RGNa, and the region RGNd includes two regions RGNd), and each of the regions RGNa, RGNb, RGNc, and RGNd may include one or more of a plurality of regions to be described with reference to FIGS. 4A, 4B, 5A, 5B, 6A, 6B, 7A, 7B, 8A, and 8B and may be referred to based on components representatively included in each region or based on a location of each region. For example, because a plurality of memory cells are able to be disposed in the region RGNa, the region RGNa may be referred to as a “memory cell array region”, and the region RGNd may be referred to as a “lower side of the memory cell array region”. In an embodiment, the region RGNa may overlap the region RGNd in a vertical direction VD. For example, because the region RGNb is able to be disposed between one memory cell array region and another memory cell array region and the region RGNc is able to be disposed on the lower side of the region RGNb, the regions RGNb and RGNc may be referred to as a “middle region”, the region RGNb may be referred to as an “upper middle region”, and the region RGNc may be referred to as a “lower middle region”. In an embodiment, the region RGNb may overlap the region RGNc in the vertical direction VD.

The semiconductor memory device 100 may include the memory cell array, first peripheral circuits, second peripheral circuits, and third peripheral circuits.

In an embodiment, the memory cell array may be disposed in the memory cell array region in the first semiconductor structure SEMS1, the first peripheral circuits may be disposed in the “upper middle region” in the first semiconductor structure SEMS1, the second peripheral circuits may be disposed in the lower middle region” in the second semiconductor structure SEMS2, and the third peripheral circuits may be disposed on “the lower side of the memory cell array region” in the second semiconductor structure SEMS2. In an embodiment, the third peripheral circuits may overlap the memory cell array region in the vertical direction VD.

In an embodiment, the memory cell array may include vertical channel transistors (VCTs). The first peripheral circuits may include the vertical channel transistors or horizontal channel transistors (HCTs). The second peripheral circuits and the third peripheral circuits may include the horizontal channel transistors. For example, the memory cell array may be implemented by using a vertical channel transistor, the first peripheral circuits may be implemented by using the vertical channel transistor or a horizontal channel transistor, and each of the second peripheral circuits and the third peripheral circuits may be implemented by using a horizontal channel transistor.

In an embodiment, the horizontal channel transistor may include a planar field effect transistor (FET), a fin field effect transistor (FinFET), a recessed channel array transistor (RCAT), sphere-RCAT (S-RCAT), a buried channel array transistor (BCAT), etc., and the vertical channel transistor may mean a transistor which includes a channel grown in a vertical channel after the horizontal channel transistor with the development of semiconductor manufacturing process technologies.

The first peripheral circuits and the second peripheral circuits disposed in the “middle region” may have a given relationship.

In an embodiment, each of the first peripheral circuits may have heat resistance under a given condition associated with the process of manufacturing the semiconductor memory device 100. For example, the heat resistance of each of the first peripheral circuits may be higher than that of the second peripheral circuits under the given condition. For example, each of the first peripheral circuits may be less sensitive with reference to the heat resistance than that of the second peripheral circuits under the given condition.

In an embodiment, each of the first peripheral circuits may have a timing margin of a given level or more in association with an operation of the semiconductor memory device 100. For example, during a data input/output operation of the semiconductor memory device 100, the timing margin of each of the first peripheral circuits may be greater than the timing margin of each of the second peripheral circuits.

In FIG. 1, the memory cell array, the first peripheral circuits, the second peripheral circuits, and the third peripheral circuits may be disposed in the regions RGNa, RGNb, RGNc, and RGNd of the semiconductor memory device 100, but the present invention is not limited thereto. In other embodiments, the semiconductor memory device 100 may further include regions, and additional peripheral circuits may be further disposed in the regions further included of the semiconductor memory device 100. Various embodiments of the semiconductor memory device 100 will be described with reference to FIGS. 4A, 5A, 6A, 7A, and 8A.

The vertical direction VD, a first horizontal direction HD1, and a second horizontal direction HD2 which are perpendicular to each other are illustrated in FIG. 1. In the following drawings, the vertical direction VD, the first horizontal direction HD1, and the second horizontal direction HD2 may be used in common. For example, the vertical direction VD may be a direction facing away from the upper surface of the first semiconductor structure SEMS1 or the second semiconductor structure SEMS2, the first horizontal direction HDI may be a direction from the memory cell array region to the upper middle region or a direction from the lower side of the memory cell array region to the lower middle region, and the second horizontal direction HD2 may be a direction perpendicular to the first horizontal direction HD1.

According to the above configuration, a semiconductor memory device of the present disclosure may include peripheral circuits disposed in the upper middle region between one memory cell array region and another memory cell array region. In the semiconductor memory device with the COP structure, the upper middle region may be a region in a first semiconductor structure where a memory cell array is formed, and peripheral circuits having a characteristic of a given level or more from among all peripheral circuits of the semiconductor memory device may be only disposed in the upper middle region in consideration of the process of manufacturing the memory cell array or an operation of the semiconductor memory device. As all the peripheral circuits of the semiconductor memory device are appropriately distributed and disposed in the upper middle region and the lower middle region, the chip size of the semiconductor memory device may be optimized.

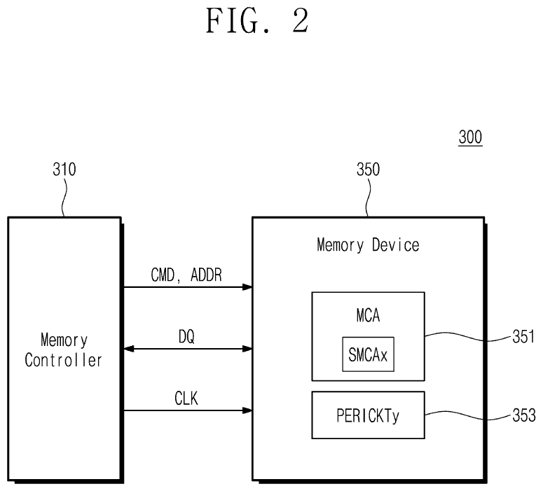

FIG. 2 is a block diagram illustrating a memory system including a semiconductor memory device according to embodiments of the present disclosure.

Referring to FIG. 2, a memory system 300 may include a memory controller 310 and a memory device 350. The memory device 350 may correspond to the semiconductor memory device 100 of FIG. 1.

The memory controller 310 may overall control operations of the memory system 300 and may overall control the data exchange between an external host device and the memory device 350. For example, the memory controller 310 may generate a command CMD and an address ADDR depending on a request of the host device. The memory controller 310 may write data indicated by a data signal DQ in the memory device 350 or may read data from the memory device 350 based on the command CMD and the address ADDR. For example, the memory controller 310 may provide the memory device 350 with a clock signal CLK for a write operation or a read operation.

The memory device 350 may include a memory cell array 351 and peripheral circuits 353. The memory cell array 351 may include a plurality of memory cells for storing data, and the plurality of memory cells may be grouped into a plurality of sub-memory cell arrays (e.g., SMCAx) (x being an integer of 2 or more). The peripheral circuits 353 (e.g., PERICKTy) (y being an integer of 2 or more) may include various circuits for writing, reading, and managing data associated with the plurality of memory cells.

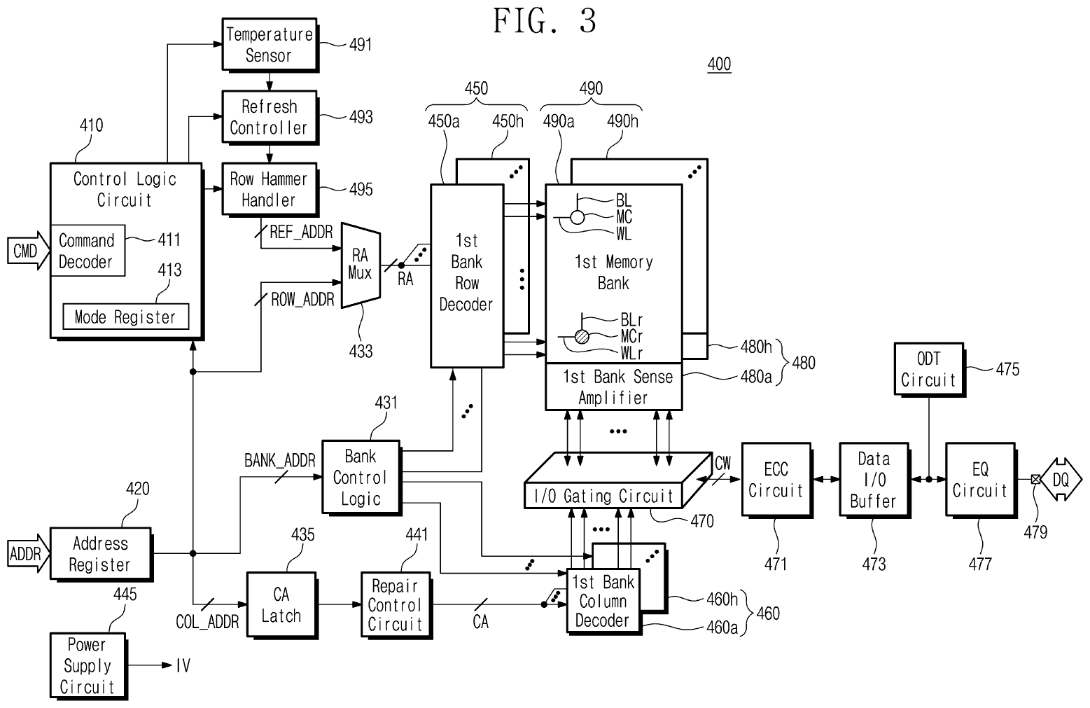

FIG. 3 is a block diagram illustrating an embodiment of the semiconductor memory device of FIG. 1 according to example embodiments.

Referring to FIG. 3, a memory device 400 may include a control logic circuit 410, an address register 420, bank control logic 431, a row address multiplexer 433, a column address latch 435, a repair control circuit 441, a power supply circuit 445, a row decoder 450, a column decoder 460, a memory cell array 490, an input/output gating circuit 470, an error correction code (ECC) circuit 471, a data input/output buffer 473, an on-die termination (ODT) circuit 475, an equalizer circuit 477, a data input/output pad 479, a sense amplifier unit 480, a temperature sensor 491, a refresh controller 493, and a row hammer handler 495. The memory device 400 may correspond to the semiconductor memory device 100 of FIG. 1 or the memory device 350 of FIG. 2.

The memory cell array 490 may include first to eighth memory banks 490a to 490h. The row decoder 450 may include first to eighth bank row decoders 450a to 450h respectively connected to the first to eighth memory banks 490a to 490h, the column decoder 460 may include first to eighth bank column decoders 460a to 460h respectively connected to the first to eighth memory banks 490a to 490h, and the sense amplifier unit 480 may include first to eighth bank sense amplifiers 480a to 480h respectively connected to the first to eighth memory banks 490a to 490h.

The first to eighth memory banks 490a to 490h, the first to eighth bank sense amplifiers 480a to 480h, the first to eighth bank row decoders 450a to 450h, and the first to eighth bank column decoders 460a to 460h may constitute first to eighth banks. Each of the first to eighth memory banks 490a to 490h may include a plurality of word lines WLs, a plurality of bit lines BLs, and a plurality of memory cells MCs formed at intersections of the word lines WLs and the bit lines BLs. Each of the first to eighth memory banks 490a to 490h may include a plurality of repair word lines WLrs, a plurality of repair bit lines BLrs, and a plurality of repair memory cells MCrs formed at intersections of the repair word lines WLrs and the repair bit lines BLrs.

The memory device 400 including eight banks is illustrated in FIG. 3, but the present invention is not limited thereto. In other embodiments, the memory device 400 may include an arbitrary number of banks, that is, 2 or more banks.

The address register 420 may receive the address ADDR including a bank address BANK_ADDR, a row address ROW_ADDR, and a column address COL_ADDR from a memory controller (e.g., 310 of FIG. 2). The address register 420 may provide the received bank address BANK_ADDR to the bank control logic 431, may provide the received row address ROW_ADDR to the row address multiplexer 433, and may provide the received column address COL_ADDR to the column address latch 435.

The bank control logic 431 may generate bank control signals in response to the bank address BANK_ADDR. A bank row decoder corresponding to the bank address BANK_ADDR from among the first to eighth bank row decoders 450a to 450h may be activated in response to the bank control signals, and a bank column decoder corresponding to the bank address BANK_ADDR from among the first to eighth bank column decoders 460a to 460h may be activated in response to the bank control signals.

The row address multiplexer 433 may receive the row address ROW_ADDR from the address register 420 and may receive a refresh row address REF_ADDR from the refresh controller 493 or the row hammer handler 495. The row address multiplexer 433 may selectively output the row address ROW_ADDR or the refresh row address REF_ADDR as a row address RA. The row address RA output from the row address multiplexer 433 may be applied to each of the first to eighth bank row decoders 450a to 450h.

A bank row decoder activated by the bank control logic 431 from among the first to eighth bank row decoders 450a to 450h may decode the row address RA output from the row address multiplexer 433 and may activate a word line corresponding to the row address RA. For example, the activated bank row decoder may apply a word line driving voltage to the word line corresponding to the row address RA. The activated bank row decoder may generate the word line driving voltage by using a power supply voltage and may provide the word line driving voltage to the corresponding word line.

The column address latch 435 may receive the column address COL_ADDR from the address register 420 and may temporarily store the received column address COL_ADDR. Also, in a burst mode, the column address latch 435 may gradually (or sequentially) increase the received column address COL_ADDR. The column address latch 435 may apply the temporarily stored column address COL_ADDR or the gradually increased column address COL_ADDR to each of the first to eighth bank column decoders 460a to 460h through the repair control circuit 441.

A bank column decoder activated by the bank control logic 431 from among the first to eighth bank column decoders 460a to 460h may activate a sense amplifier corresponding to the bank address BANK_ADDR and the column address COL_ADDR through the input/output gating circuit 470.

The input/output gating circuit 470 may include the following together with circuits gating input/output data: input data mask logic, read data latches for storing data output from the first to eighth memory banks 490a to 490h, and write drivers for writing data in the first to eighth memory banks 490a to 490h.

Data read from one memory bank among the first to eighth memory banks 490a to 490h may be sensed by a sense amplifier corresponding to the one sense amplifier among the first to eighth bank sense amplifiers 480a to 480h and may be stored in the read data latches.

The data stored in the read data latches may be provided to the memory controller through the ECC circuit 471, the data input/output buffer 473, the equalizer circuit 477, and the data input/output pad 479. Data to be written in one memory bank among the first to eighth memory banks 490a to 490h may be provided from the memory controller to the data input/output buffer 473 through the data input/output pad 479 and the equalizer circuit 477. The data provided to the data input/output buffer 473 may be provided to the input/output gating circuit 470 through the ECC circuit 471.

The control logic circuit 410 may control operations of the memory device 400. For example, the control logic circuit 410 may generate control signals such that the memory device 400 performs the write operation or the read operation. The control logic circuit 410 may include a command decoder 411 which decodes the command CMD received from the memory controller and a mode register 413 for setting an operation mode of the memory device 400.

In an embodiment, the control logic circuit 410 may output a control signal for controlling the ODT circuit 475, and the ODT circuit 475 may turn on/turn off one or more switches capable of being included within the ODT circuit 475, based on the control signal.

The repair control circuit 441 may receive the column address COL_ADDR from the column address latch 435, may compare the received column address COL_ADDR and a failed cell address indicating failed cells of the first to eighth memory banks 490a to 490h, and may provide a repair control signal to the column decoder 460. In an embodiment, the repair control circuit 441 may include a failed cell memory storing failed cell information for identifying a cell region to which failed cells belong, and the column decoder 460 may perform a column repair operation based on the repair control signal.

The power supply circuit 445 may provide various powers for operations of various components included in the memory device 400.

The ECC circuit 471 may encode pieces of write data to be written in the first to eighth memory banks 490a to 490h to generate parity symbols and may provide a codeword CW including the pieces of write data and the parity symbols to the input/output gating circuit 470. The ECC circuit 471 may decode the codeword CW read from the first to eighth memory banks 490a to 490h to generate pieces of read data and may provide the pieces of read data to the data input/output buffer 473.

The ODT circuit 475 may perform impedance matching and may prevent the quality of a transmission line from being reduced, that is, the data signal DQ included in the data transmitted through the data input/output pad 479 from being reflected as a noise signal at the end of the transmission line.

The equalizer circuit 477 may compensate for the loss which is caused in the process of transmitting the data signal DQ at high speed.

The refresh controller 493 may provide the refresh address REF_ADDR for performing the refresh operation for compensating for leakage currents of the plurality of memory cells MCs or the plurality of repair memory cells MCrs included in the first to eighth memory banks 490a to 490h.

The temperature sensor 491 may detect a temperature determined in advance and may provide a temperature signal corresponding to the detected temperature to the refresh controller 493. The refresh controller 493 may change a refresh period depending on the detected temperature. For example, the refresh controller 493 may perform a temperature compensated self-refresh (TCSR) operation.

The row hammer handler 495 may provide the refresh address REF_ADDR for performing a hammer refresh operation for memory cells of a victim row address adjacent to an aggressor row address frequently accessed.

In an embodiment, the first to eighth memory banks 490a to 490h may correspond to the plurality of sub-memory cell arrays described with reference to FIG. 2. For example, each of the first to eighth memory banks 490a to 490h may correspond to one sub-memory cell array.

The various components 410, 411, 413, 420, 431, 433, 435, 441, 445, 450, 460, 470, 471, 473, 475, 477, 480, 490, 491, 493, and 495 included in the memory device 400 are illustrated in FIG. 3, but the memory device 400 may further include any other components not illustrated in FIG. 3.

For example, the memory device 400 may further include sub-word line drivers for driving the plurality of memory cells MCs or the plurality of repair memory cells MCrs or bit line sense amplifiers for sensing voltage levels of the bit lines BLs or the repair bit lines BLrs.

For example, the memory device 400 may further include input/output line driving circuits for driving local input/output lines and global input/output lines transferring the voltage levels sensed by the bit line sense amplifiers to the input/output gating circuit 470.

For example, the memory device 400 may further include pre-decoders which are connected to the address register 420 and decode the row address ROW_ADDR or the column address COL_ADDR to provide additional information to the row decoder 450 or the column decoder 460.

For example, the memory device 400 may further include anti-fuse circuits for various settings associated with operations of the memory device 400, power/signal pads for transferring powers or signals provided from the outside, and an electrostatic protection circuit for protection against the electrical impact from the outside.

FIG. 4A is a cross-sectional view of the semiconductor memory device taken along line X-X′ of FIG. 1 according to example embodiments. FIG. 4B is a diagram for describing a memory cell array and peripheral circuits disposed in regions of FIG. 4A according to example embodiments. FIG. 4C is a graph for describing characteristics of first peripheral circuits and second peripheral circuits disposed in regions of FIG. 4A according to example embodiments.

A semiconductor memory device 100a of FIG. 4A may correspond to the semiconductor memory device 100 of FIG. 1, and the semiconductor memory device 100a may include the first semiconductor structure SEMS1 and the second semiconductor structure SEMS2 disposed under (or on the lower side of) the first semiconductor structure SEMS1. In an embodiment, the first semiconductor structure SEMS1 may overlap the second semiconductor structure SEMS2 in the vertical direction VD.

A memory region MRGN, a first region RGN1, a second region RGN2, and a third region RGN3 are illustrated in FIG. 4A, and the memory region MRGN may be inner regions of the first semiconductor structure SEMS1, and the second region RGN2 and the third region RGN3 may be inner regions of the second semiconductor structure SEMS2. In the semiconductor memory device 100a, each of the memory region MRGN and the third region RGN3 may include two or more regions.

In an embodiment, the memory region MRGN, the first region RGN1, the second region RGN2, and third region RGN3 may respectively correspond to the region RGNa, the region RGNb, the region RGNc, and the region RGNd of FIG. 1.

For example, the memory region MRGN may be included in the memory cell array region of FIG. 1, the first region RGN1 may be included in the “upper middle region” of FIG. 1, the second region RGN2 may be included in the “lower middle region” of FIG. 1, and the third region RGN3 may be included (or disposed) on “the lower side of the memory cell array region” of FIG. 1. In an embodiment, the second region RGN2 may overlap a part of the first region RGN1 in the vertical direction VD.

In an embodiment, the memory region MRGN and the first region RGN1 may be sequentially disposed along the first horizontal direction HD1 or a direction facing away from the first horizontal direction HD1 within the first semiconductor structure SEMS1, and the third region RGN3 and the second region RGN2 may be sequentially disposed along the first horizontal direction HD1 or the direction facing away from the first horizontal direction HDI within the second semiconductor structure SEMS2.

Referring to FIG. 4B, as in the semiconductor memory device 100 of FIG. 1, the semiconductor memory device 100a may include a memory cell array MCA, first peripheral circuits PERICKT1s, second peripheral circuits PERICKT2s, and third peripheral circuits PERICKT3s. Accordingly, the memory cell array MCA may be disposed in the memory region MRGN, the first peripheral circuits PERICKT1s may be disposed in the first region RGN1, the second peripheral circuits PERICKT2s may be disposed in the second region RGN2, and the third peripheral circuits PERICK3s may be disposed in the third region RGN3.

In an embodiment, the memory cell array MCA may include vertical channel transistors VCTs. The first peripheral circuits PERICKT1s may include the vertical channel transistors VCTs or horizontal channel transistors HCTs. Each of the second peripheral circuits PERICKT2s and the third peripheral circuits PERICKT3s may include the horizontal channel transistors.

Referring to FIG. 4C, because the first peripheral circuits PERICKT1s are included in the “upper middle region” of FIG. 1 and the second peripheral circuits PERICKT2s are included in the “lower middle region” of FIG. 1, the first peripheral circuits PERICKT1s and the second peripheral circuits PERICKT2s may be disposed in the “middle region” of FIG. 1, and the peripheral circuits disposed in the “middle region” may have a given relationship.

In an embodiment, each of the first peripheral circuits PERICKT1s may have heat resistance under a first condition associated with the process of manufacturing the semiconductor memory device 100a.

For example, the first condition may be associated with the process of manufacturing each memory cell included in the memory cell array MCA. Each memory cell may include a cell transistor and a cell capacitor, and the first condition may mean a physical or chemical impact which is applied to the semiconductor memory device 100a in the process of forming the cell capacitor on the upper side of the cell transistor after the cell transistor is formed. The first peripheral circuits disposed in the “upper middle region” may be more exposed to the physical or chemical impact under the first condition than the second peripheral circuits disposed in the “lower middle region”, and in particular, a peripheral temperature of the first peripheral circuits may increase to be higher than a peripheral temperature of the second peripheral circuits. This may mean that circuits vulnerable to the physical or chemical impact under the first condition are able to be selected as the second peripheral circuits rather than the first peripheral circuits. For example, the heat resistance of each of the first peripheral circuits PERICKT1s may be greater than the heat resistance of the second peripheral circuits PERICKT2s under the first condition. For example, as illustrated in FIG. 4C, the average (Avg.) heat resistance of the first peripheral circuits PERICKT1s may be greater than the average (Avg.) heat resistance of the second peripheral circuits PERICKT2s under the first condition. In this case, a reference value REFV may be a reference temperature associated with the first condition, and the first peripheral circuits PERICKT1s and the second peripheral circuits PERICKT2s may be determined based on the reference value REFV.

In an embodiment, each of the first peripheral circuits PERICKT1s may have a timing margin of a given level or more in association with an operation of the semiconductor memory device 100a. For example, during the data input/output operation of the semiconductor memory device 100a, the timing margin of each of the first peripheral circuits PERICKT1s may be greater than the timing margin of each of the second peripheral circuits PERICKT2s. The timing margin may include an operating speed of each of the first and second peripheral circuits PERICKT1s and PERICKT2s and may include setup times or hold times of various kinds of signals. The timing margin may be associated with the signal integrity of signals which the first peripheral circuits PERICKT1s transmits/receives. For example, the timing margin of each of the first peripheral circuits PERICKT1s may be greater than the timing margin of each of the second peripheral circuits PERICKT2s. For example, as illustrated in FIG. 4C, the average (Avg.) timing margin of the first peripheral circuits PERICKT1s may be greater than the average timing margin of the second peripheral circuits PERICKT2s. In this case, the reference value REFV may be a reference timing margin, and the first peripheral circuits PERICKT1s and the second peripheral circuits PERICKT2s may be determined based on the reference value REFV. For other examples, an operating speed of each of the first peripheral circuits PERICKT1s may be slower than an operating speed of each of the second peripheral circuits PERICKT2s.

In an embodiment, the first peripheral circuits PERICKT1s may include one or more of the mode register 413, the refresh controller 493, the row hammer handler 495, and the power supply circuit 445 described with reference to FIG. 3, but this is only an example. For example, the first peripheral circuits PERICKT1s may include at least one of the mode register 413, the refresh controller 493, the row hammer handler 495, and the power supply circuit 445 described with reference to FIG. 3. In another embodiment, the first peripheral circuits PERICKT1s may further include the anti-fuse circuits, the power/signal pads, and the pre-decoders described with reference to FIG. 3.

In an embodiment, the second peripheral circuits PERICKT2s may include one or more of the command decoder 411, the data input/output buffer 473, and the ODT circuit 475 described with reference to FIG. 3, but this is only an example. For example, the second peripheral circuits PERICKT2s may include at least one of the command decoder 411, the data input/output buffer 473, and the ODT circuit 475 described with reference to FIG. 3. In another embodiment, the second peripheral circuits PERICKT2s may further include the equalizer circuit 477 described with reference to FIG. 3.

In an embodiment, the third peripheral circuits PERICKT3s may include one or more of the bit line sense amplifiers, the sub-word line drivers, the row decoder 450, and the column decoder 460 described with reference to FIG. 3, but this is only an example. For example, the third peripheral circuits PERICKT3s may include at least one of the bit line sense amplifiers, the sub-word line drivers, the row decoder 450, and the column decoder 460 described with reference to FIG. 3. In another embodiment, the third peripheral circuits PERICKT3s may further include input/output line driving circuits for driving local input/output lines and global input/output lines transferring voltage levels sensed by the bit line sense amplifiers to input/output gating circuits.

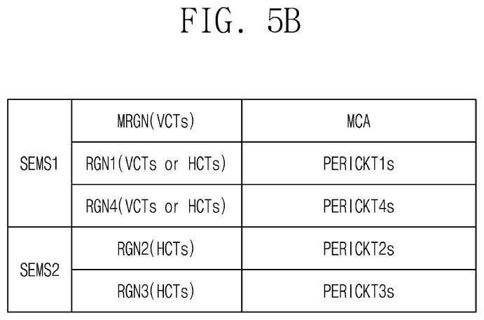

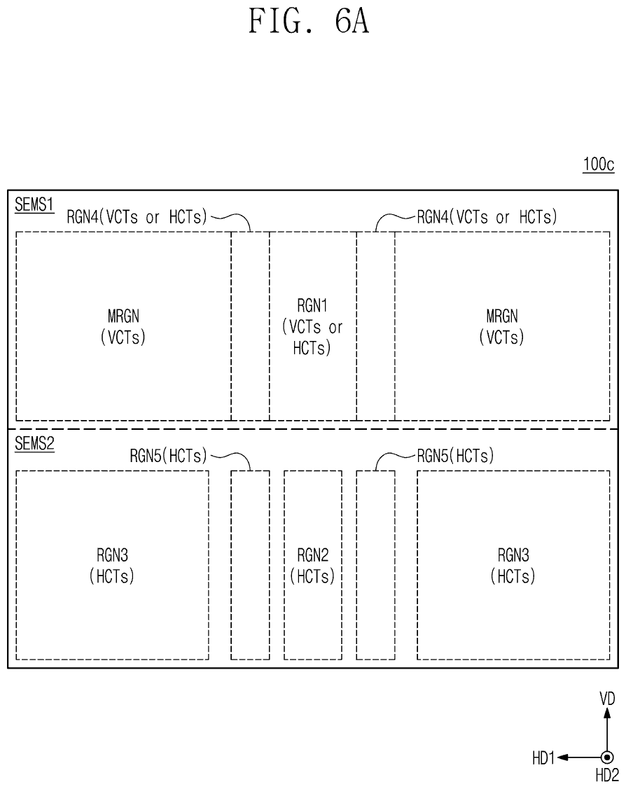

FIG. 5A is a cross-sectional view of the semiconductor memory device taken along line X-X′ of FIG. 1 according to example embodiments. FIG. 5B is a diagram for describing a memory cell array and peripheral circuits disposed in regions of FIG. 5A according to example embodiments.

A semiconductor memory device 100b of FIG. 5A may correspond to the semiconductor memory device 100 of FIG. 1, and the semiconductor memory device 100b may include the first semiconductor structure SEMS1 and the second semiconductor structure SEMS2 disposed under (or on the lower side of) the first semiconductor structure SEMS1. In an embodiment, the first semiconductor structure SEMS1 may overlap the second semiconductor structure SEMS2 in the vertical direction VD.

The memory region MRGN, the first region RGN1, the second region RGN2, the third region RGN3, and a fourth region RGN4 are illustrated in FIG. 5A, the memory region MRGN, the first region RGN1, and the fourth region RGN4 may be inner regions of the first semiconductor structure SEMS1, and the second region RGN2 and the third region RGN3 may be inner regions of the second semiconductor structure SEMS2. In the semiconductor memory device 100b, each of the memory region MRGN, the third region RGN3, and the fourth region RGN4 may include two or more regions. In an embodiment, the fourth region RGN4 may overlap a part of the second semiconductor structure SEMS2 in the vertical direction VD.

The semiconductor memory device 100b of FIG. 5A may be the same as or similar to the semiconductor memory device 100a of FIG. 4A except that the fourth region RGN4 is further included, and thus, additional description will be omitted to avoid redundancy. The fourth region RGN4 may be disposed between the memory region MRGN and the first region RGN1.

In an embodiment, the memory region MRGN, the fourth region RGN4, and the first region RGN1 may be sequentially disposed along the first horizontal direction HDI or the direction facing away from the first horizontal direction HDI within the first semiconductor structure SEMS1, and this is only an example.

Referring to FIG. 5B, as in the semiconductor memory device 100a of FIG. 4A, the semiconductor memory device 100b may further include the memory cell array MCA, the first peripheral circuits PERICKT1s, the second peripheral circuits PERICKT2s, the third peripheral circuits PERICKT3s, and fourth peripheral circuits PERICKT4s. Accordingly, the memory cell array MCA may be disposed in the memory region MRGN, the first peripheral circuits PERICKT1s may be disposed in the first region RGN1, the second peripheral circuits PERICKT2s may be disposed in the second region RGN2, and the third peripheral circuits PERICKT3s may be disposed in the third region RGN3. The fourth peripheral circuits PERICKT4s may be disposed in the fourth region RGN4.

In an embodiment, as in the first peripheral circuits PERICKT1s, the fourth peripheral circuits PERICKT4s may include the vertical channel transistors VCTs or horizontal channel transistors HCTs.

In an embodiment, as in the first peripheral circuits PERICKT1s, the fourth peripheral circuits PERICKT4s may have the heat resistance under the first condition associated with the process of manufacturing the semiconductor memory device 100b and may have the timing margin of a given level or more in association with the operation of the semiconductor memory device 100b. However, the present invention is not limited thereto.

In an embodiment, the fourth peripheral circuits PERICKT4s may include the repair control circuit 441 described with reference to FIG. 3, and this is only an example.

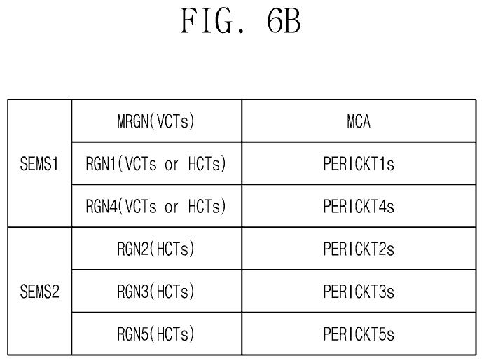

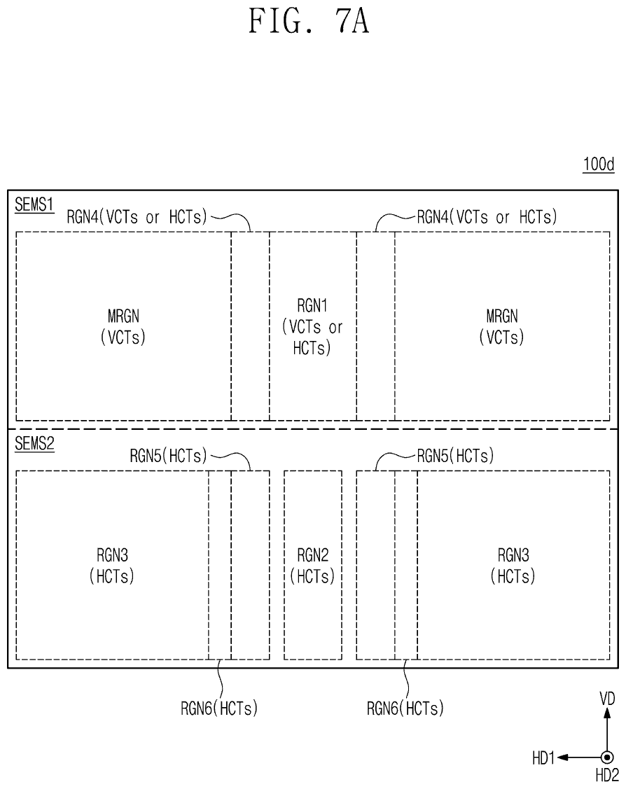

FIG. 6A is a cross-sectional view of the semiconductor memory device taken along line X-X′ of FIG. 1 according to example embodiments. FIG. 6B is a diagram for describing a memory cell array and peripheral circuits disposed in regions of FIG. 6A according to example embodiments.

A semiconductor memory device 100c of FIG. 6A may correspond to the semiconductor memory device 100 of FIG. 1, and the semiconductor memory device 100c may include the first semiconductor structure SEMS1 and the second semiconductor structure SEMS2 disposed under (or on the lower side of) the first semiconductor structure SEMS1. In an embodiment, the first semiconductor structure SEMS1 may overlap the second semiconductor structure SEMS2 in the vertical direction VD.

The memory region MRGN, the first region RGN1, the second region RGN2, the third region RGN3, the fourth region RGN4, a fifth region RGN5 are illustrated in FIG. 6A, the memory region MRGN, the first region RGN1, and the fourth region RGN4 may be inner regions of the first semiconductor structure SEMS1, and the second region RGN2, the third region RGN3, and the fifth region RGN5 may be inner regions of the second semiconductor structure SEMS2. In the semiconductor memory device 100c, each of the memory region MRGN, the third region RGN3, the fourth region RGN4, and the fifth region RGN5 may include two or more regions.

The semiconductor memory device 100c of FIG. 6A may be the same as or similar to the semiconductor memory device 100b of FIG. 5A except that the fifth region RGN5 is further included, and thus, additional description will be omitted to avoid redundancy. The fifth region RGN5 may be disposed on the lower side of the fourth region RGN4. In an embodiment, the fifth region RGN5 may overlap the fourth region RGN4 in the vertical direction VD.

In an embodiment, the third region RGN3, the fifth region RGN5, and the second region RGN2 may be sequentially disposed along the first horizontal direction HD1 or the direction facing away from the first horizontal direction HD1 within the second semiconductor structure SEMS2, and this is only an example.

Referring to FIG. 6B, as in the semiconductor memory device 100b of FIG. 5A, the semiconductor memory device 100c may include the memory cell array MCA, the first peripheral circuits PERICKT1s, the second peripheral circuits PERICKT2s, the third peripheral circuits PERICKT3s, and the fourth peripheral circuits PERICKT4s, and further include fifth peripheral circuits PERICKT5s. Accordingly, the memory cell array MCA may be disposed in the memory region MRGN, the first peripheral circuits PERICKT1s may be disposed in the first region RGN1, the second peripheral circuits PERICKT2s may be disposed in the second region RGN2, and the third peripheral circuits PERICKT3s may be disposed in the third region RGN3. The fourth peripheral circuits PERICKT4s may be disposed in the fourth region RGN4. The fifth peripheral circuits PERICKT5s may be disposed in the fifth region RGN5.

In an embodiment, as in the second peripheral circuits PERICKT2s or the third peripheral circuits PERICKT3s, the fifth peripheral circuits PERICKT5s may include the horizontal channel transistors HCTs.

In an embodiment, a characteristic of the fifth peripheral circuits PERICKT5s may be similar to that of the second peripheral circuits PERICKT2s or the third peripheral circuits PERICKT3s.

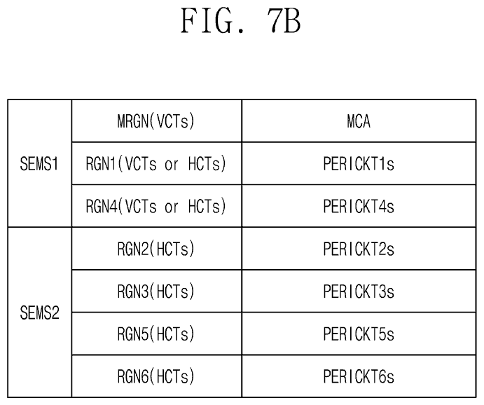

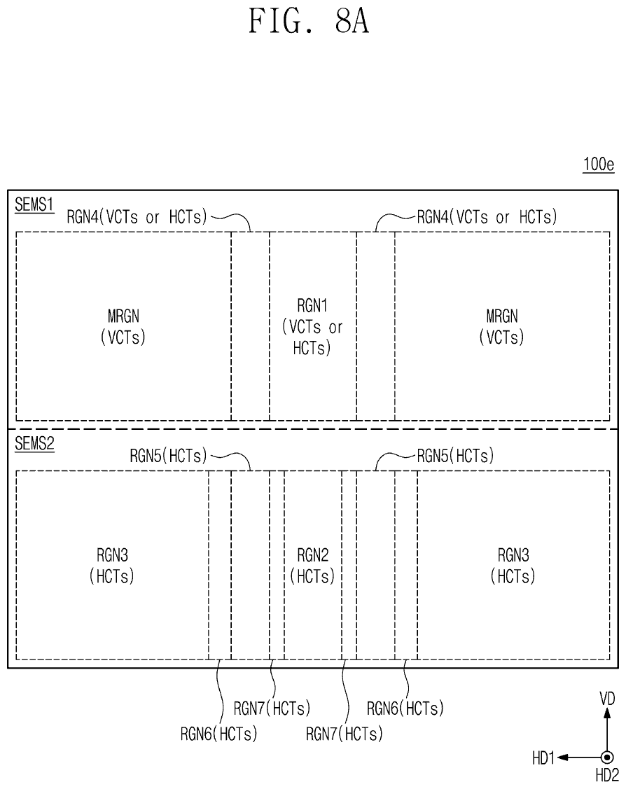

In an embodiment, the fifth peripheral circuits PERICKT5s may include the ECC circuit 471 described with reference to FIG. 3, and this is only an example. FIG. 7A is a cross-sectional view of the semiconductor memory device taken along line X-X′ of FIG. 1 according to example embodiments. FIG. 7B is a diagram for describing a memory cell array and peripheral circuits disposed in regions of FIG. 7A according to example embodiments.

A semiconductor memory device 100d of FIG. 7A may correspond to the semiconductor memory device 100 of FIG. 1, and the semiconductor memory device 100d may include the first semiconductor structure SEMS1 and the second semiconductor structure SEMS2 disposed under (or on the lower side of) the first semiconductor structure SEMS1. In an embodiment, the first semiconductor structure SEMS1 may overlap the second semiconductor structure SEMS2 in the vertical direction VD.

The memory region MRGN, the first region RGN1, the second region RGN2, the third region RGN3, the fourth region RGN4, the fifth region RGN5, and a sixth region RGN6 are illustrated in FIG. 7A, the memory region MRGN, the first region RGN1, and the fourth region RGN4 may be inner regions of the first semiconductor structure SEMS1, and the second region RGN2, the third region RGN3, the fifth region RGN5, and the sixth region RGN6 may be inner regions of the second semiconductor structure SEMS2. In the semiconductor memory device 100d, each of the memory region MRGN, the third region RGN3, the fourth region RGN4, the fifth region RGN5, and the sixth region RGN6 may include two or more regions.

The semiconductor memory device 100d of FIG. 7A may be the same as or similar to the semiconductor memory device 100c of FIG. 6A except that the sixth region RGN6 is further included, and thus, additional description will be omitted to avoid redundancy. The sixth region RGN6 may be disposed on the lower side of the memory region MRGN. In an embodiment, the sixth region RGN6 may overlap a part of the memory region MRGN in the vertical direction VD.

In an embodiment, the third region RGN3, the sixth region RGN6, the fifth region RGN5, and the second region RGN2 may be sequentially disposed along the first horizontal direction HD1 or the direction facing away from the first horizontal direction HD1 within the second semiconductor structure SESM2, and this is only an example.

Referring to FIG. 7B, as in the semiconductor memory device 100c of FIG. 6A, the semiconductor memory device 100d may include the memory cell array MCA, the first peripheral circuits PERICKT1s, the second peripheral circuits PERICKT2s, the third peripheral circuits PERICKT3s, the fourth peripheral circuits PERICKT4s, and the fifth peripheral circuits PERICKT5s, and further include sixth peripheral circuits PERICKT6s. Accordingly, the memory cell array MCA may be disposed in the memory region MRGN, the first peripheral circuits PERICKT1s may be disposed in the first region RGN1, the second peripheral circuits PERICKT2s may be disposed in the second region RGN2, and the third peripheral circuits PERICKT3s may be disposed in the third region RGN3. The fourth peripheral circuits PERICKT4s may be disposed in the fourth region RGN4, and the fifth peripheral circuits PERICKT5s may be disposed in the fifth region RGN5. The sixth peripheral circuits PERICKT6s may be disposed in the sixth region RGN6.

In an embodiment, as in the second peripheral circuits PERICKT2s, the third peripheral circuits PERICKT3s, or the fifth peripheral circuits PERICKT5s, the sixth peripheral circuits PERICKT6s may include the horizontal channel transistors HCTs.

In an embodiment, a characteristic of the sixth peripheral circuits PERICKT6s may be similar to that of the second peripheral circuits PERICKT2s, the third peripheral circuits PERICKT3s, or the fifth peripheral circuits PERICKT5s.

In an embodiment, the sixth peripheral circuits PERICKT6s may include the input/output line driving circuit described with reference to FIG. 3, and this is only an example.

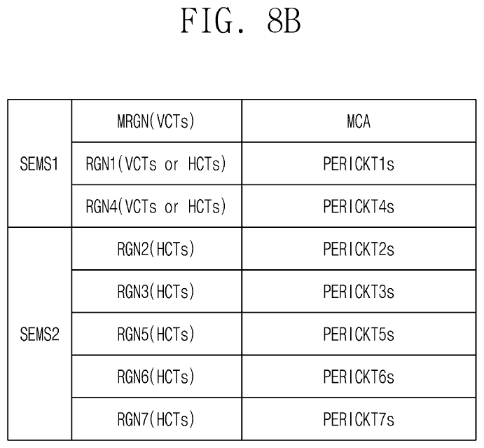

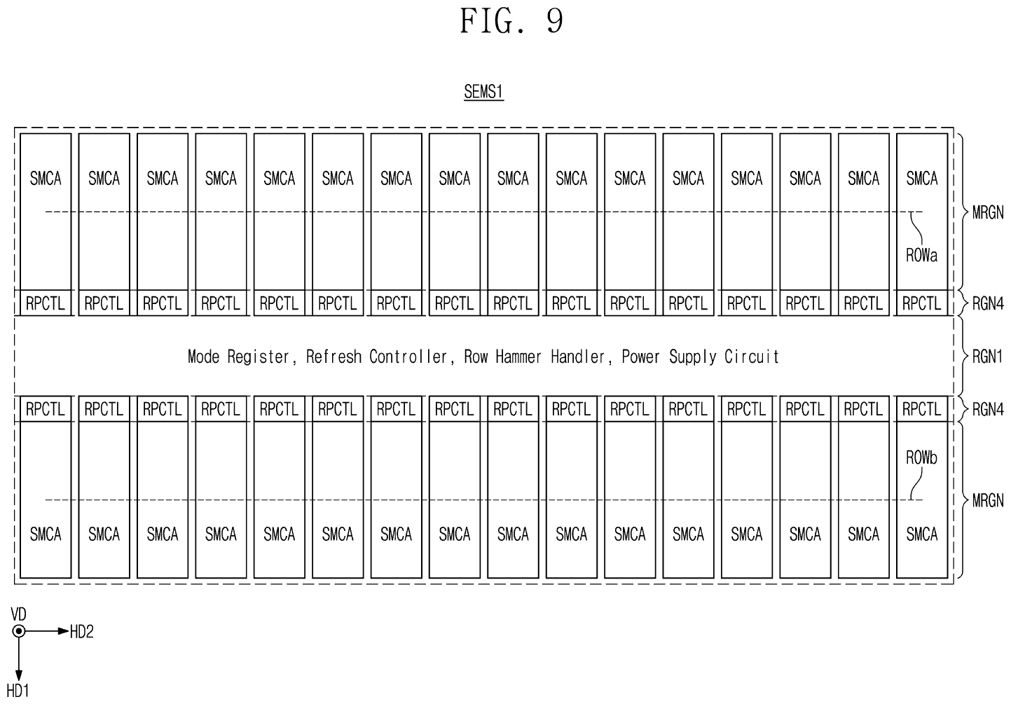

FIG. 8A is a cross-sectional view of the semiconductor memory device taken along line X-X′ of FIG. 1 according to example embodiments. FIG. 8B is a diagram for describing a memory cell array and peripheral circuits disposed in regions of FIG. 8A according to example embodiments.

A semiconductor memory device 100e of FIG. 8A may correspond to the semiconductor memory device 100 of FIG. 1, and the semiconductor memory device 100e may include the first semiconductor structure SEMS1 and the second semiconductor structure SEMS2 disposed under (or on the lower side of) the first semiconductor structure SEMS1. In an embodiment, the first semiconductor structure SEMS1 may overlap the second semiconductor structure SEMS2 in the vertical direction VD.

The memory region MRGN, the first region RGN1, the second region RGN2, the third region RGN3, the fourth region RGN4, the fifth region RGN5, the sixth region RGN6, and a seventh region RGN7 are illustrated in FIG. 8A, the memory region MRGN, the first region RGN1, and the fourth region RGN4 may be inner regions of the first semiconductor structure SEMS1, and the second region RGN2, the third region RGN3, the fifth region RGN5, the sixth region RGN6, and the seventh region RGN7 may be inner regions of the second semiconductor structure SEMS2.

In the semiconductor memory device 100e, each of the memory region MRGN, the third region RGN3, the fourth region RGN4, the fifth region RGN5, the sixth region RGN6, and the seventh region RGN7 may include two or more regions.

The semiconductor memory device 100e of FIG. 8A may be the same as or similar to the semiconductor memory device 100d of FIG. 7A except that the seventh region RGN7 is further included, and thus, additional description will be omitted to avoid redundancy. The seventh region RGN7 may be disposed on the lower side of the first region RGN1. In an embodiment, the seventh region RGN7 may overlap a part of the first region RGN1 in the vertical direction VD.

In an embodiment, the third region RGN3, the sixth region RGN6, the seventh region RGN7, and the second region RGN2 may be sequentially disposed along the first horizontal direction HD1 or the direction facing away from the first horizontal direction HD1 within the second semiconductor structure SESM2, and this is only an example.

Referring to FIG. 8B, as in the semiconductor memory device 100d of FIG. 7A, the semiconductor memory device 100e may include the memory cell array MCA, the first peripheral circuits PERICKT1s, the second peripheral circuits PERICKT2s, the third peripheral circuits PERICKT3s, the fourth peripheral circuits PERICKT4s, the fifth peripheral circuits PERICKT5s, and the sixth peripheral circuits PERICKT6s and may further include seventh peripheral circuits PERICKT7s. Accordingly, the memory cell array MCA may be disposed in the memory region MRGN, the first peripheral circuits PERICKT1s may be disposed in the first region RGN1, the second peripheral circuits PERICKT2s may be disposed in the second region RGN2, and the third peripheral circuits PERICKT3s may be disposed in the third region RGN3. the fourth peripheral circuits PERICKT4s may be disposed in the fourth region RGN4, the fifth peripheral circuits PERICKT5s may be disposed in the fifth region RGN5, and the sixth peripheral circuits PERICKT6s may be disposed in the sixth region RGN6. The seventh peripheral circuits PERICKT7s may be disposed in the seventh region RGN7.

In an embodiment, as in the second peripheral circuits PERICKT2s, the third peripheral circuits PERICKT3s, the fifth peripheral circuits PERICKT5s, or the sixth peripheral circuits PERICKT6s, the seventh peripheral circuits PERICKT7s may include the horizontal channel transistors HCTs.

In an embodiment, a characteristic of the seventh peripheral circuits PERICKT7s may be similar to that of the second peripheral circuits PERICKT2s, the third peripheral circuits PERICKT3s, the fifth peripheral circuits PERICKT5s, or the sixth peripheral circuits PERICKT6s.

In an embodiment, the seventh peripheral circuits PERICKT7s may include the electrostatic protection circuit described with reference to FIG. 3, and this is only an example.

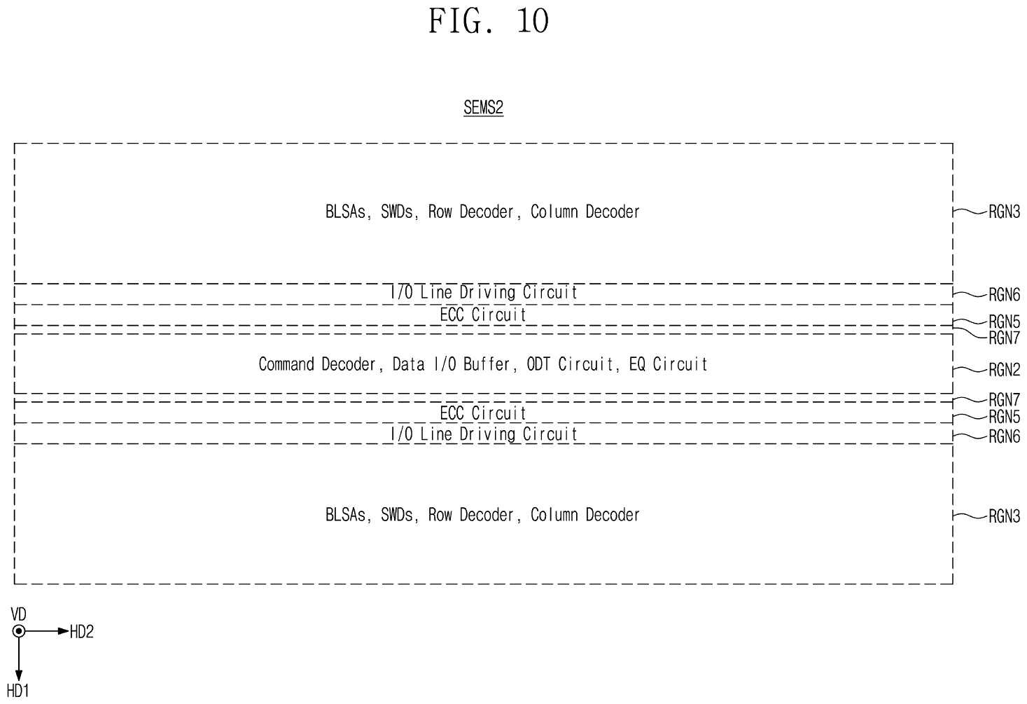

FIG. 9 is a plan view for describing the first semiconductor structure of FIG. 1 according to example embodiments.

Referring to FIG. 9, the first semiconductor structure SEMS1 may include a plurality of sub-memory cell arrays SMCAs, bank repair control circuits RPCTLs, a mode register, a refresh controller, a row hammer handler, and a power supply circuit.

Referring to FIGS. 4A, 5A, 6A, 7A, 8A and 9, the plurality of sub-memory cell arrays SMCAs may be disposed in the memory region MRGN, the bank repair control circuits RPCTLs may be disposed in the fourth region RGN4, and the mode register, the refresh controller, the row hammer handler, and the power supply circuit may be disposed in the first region RGN1. The plurality of sub-memory cell arrays SMCAs may respectively correspond to the bank repair control circuits RPCTLs.

In an embodiment, the plurality of sub-memory cell arrays SMCAs may constitute the memory cell array 490 of FIG. 9, and the bank repair control circuits RPCTLs may constitute the repair control circuit 441 of FIG. 3. The mode register, the refresh controller, the row hammer handler, and the power supply circuit may correspond to first peripheral circuits.

In an embodiment, the memory cell array 490 may include a plurality of first sub-memory cell arrays and a plurality of second sub-memory cell arrays. The plurality of first sub-memory cell arrays may be the sub-memory cell arrays SMCAs disposed at a first row ROWa in a memory cell array, and the plurality of second sub-memory cell arrays may be sub-memory cell arrays SMCAs disposed at a second row ROWb in a memory cell array. For example, the plurality of first sub-memory cell arrays may be disposed at the first row ROWa in the memory cell array so as to be adjacent to each other in the second horizontal direction HD2, and the plurality of second sub-memory cell arrays may be disposed at the second row ROWb in the memory cell array so as to be adjacent to each other in the second horizontal direction HD2.

In an embodiment, the first peripheral circuits may be disposed between the plurality of first sub-memory cell arrays and the plurality of second sub-memory cell arrays in the first horizontal direction HD1.

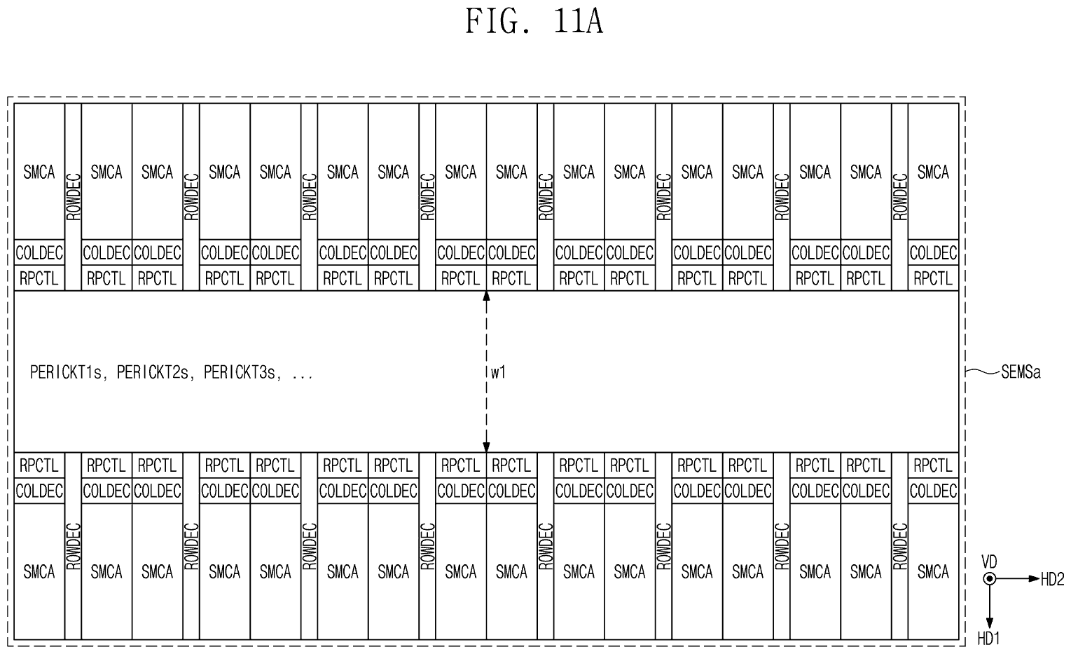

FIG. 10 is a plan view for describing the second semiconductor structure of FIG. 1 according to example embodiments.

Referring to FIG. 10, the second semiconductor structure SEMS2 may include bit line sense amplifiers BLSAs, sub-word line drivers SWDs, a row decoder, a column decoder, an input/output line driving circuit, an ECC circuit, a command decoder, a data input/output buffer, an ODT circuit, and an EQ circuit.

Referring to FIGS. 8A and 10, the bit line sense amplifiers BLSAs, the sub-word line drivers SWDs, the row decoder, and the column decoder may be disposed in the third region RGN3, the input/output line driving circuit may be disposed in the sixth region RGN6, and the ECC circuit may be disposed in the fifth region RGN5. The command decoder, the data input/output buffer, the ODT circuit, and the EQ circuit may be disposed in the second region RGN2. Although not illustrated in FIG. 10, the electrostatic protection circuit may be disposed in the seventh region RGN7.

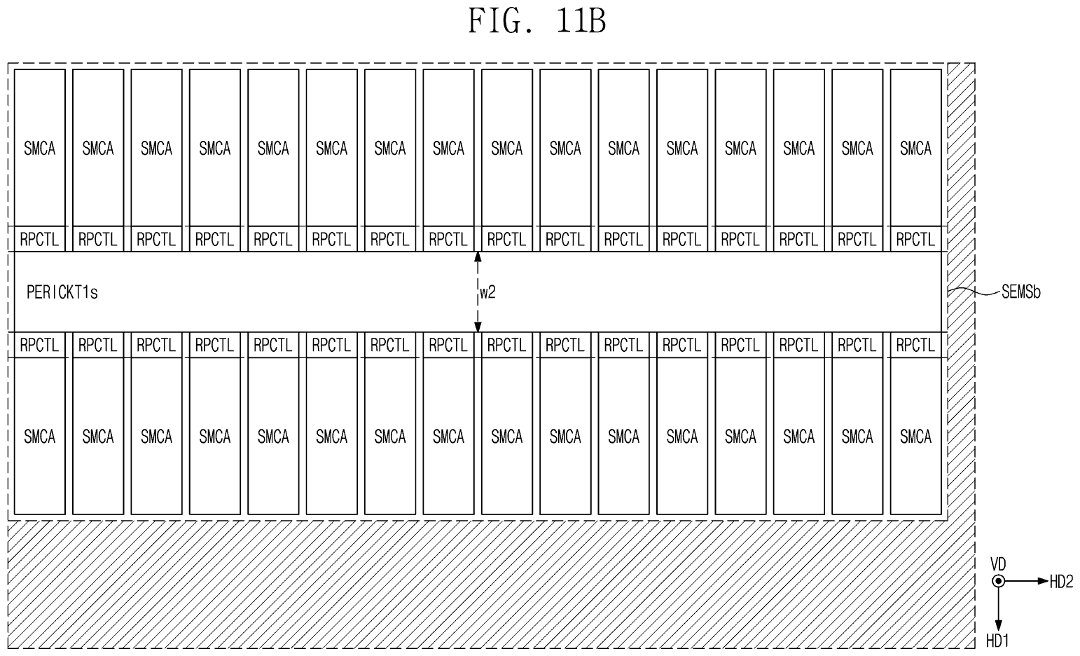

FIGS. 11A and 11B are diagrams for describing the reduction of a chip size by a semiconductor memory device according to an embodiment of the present disclosure.

A semiconductor structure SEMSa is illustrated in FIG. 11A, and a semiconductor structure SEMSb is illustrated in FIG. 11B. The semiconductor structure SEMSa may show the placement of components of a conventional semiconductor memory device not having the COP structure, and the semiconductor structure SEMSb may show the placement of some of components of a semiconductor memory device with the COP structure according to an embodiment of the present disclosure. For example, the semiconductor structure SEMSb may be the first semiconductor structure SEMS1 described with reference to FIGS. 1, 4A, 5A, 6A, 7A, 8A, and 9.

Referring to FIG. 11A, the semiconductor structure SEMSa may include the plurality of sub-memory cell arrays SMCAs, row decoders ROWDECs, column decoders COLDECs, the bank repair control circuits RPCTLs, the first peripheral circuits PERICKT1s, the second peripheral circuits PERICKT2s, the third peripheral circuits PERICKT3s, etc. As illustrated in FIG. 11A, one row decoder ROWDEC may be disposed between two sub-memory cell arrays SMCAs, and one column decoder COLDEC and one bank repair control circuit RPCTL may operate for one sub-memory cell array SMCA.

Referring to FIG. 11B, the semiconductor structure SEMSb may include the plurality of sub-memory cell arrays SMCAs, the bank repair control circuits RPCTLs, the first peripheral circuits PERICKT1s, etc. As illustrated in FIG. 11B, the row decoders ROWDECs and the column decoders COLDECs may be disposed on the lower side of the plurality of sub-memory cell arrays SMCAs, and the second peripheral circuits PERICKT2s, the third peripheral circuits PERICKT3s, etc. may also be disposed on the lower sides of the plurality of sub-memory cell arrays SMCAs or the first peripheral circuits PERICKT1s.

In the semiconductor structure SEMSa, a region where the first to third peripheral circuits PERICKT1s, PERICKT2s, PERICKT3s, . . . , and the like are disposed may correspond to the “middle region” described with reference to FIG. 1. In the semiconductor structure SEMSb, a region where the first peripheral circuits PERICKT1s are disposed may correspond to the “middle region”. Comparing the “middle regions” of the semiconductor structures SEMSa and SEMSb, the width of the “middle region” of the semiconductor structure SEMSa in the first horizontal direction HD1 may be w1, the width of the “middle region” of the semiconductor structure SEMSb in the first horizontal direction HD1 may be w2, and w2 may be reduced to less than the half of w1. Also, in the semiconductor structure SEMSb, the row decoders ROWDECs and the column decoders COLDECs of the semiconductor structure SEMSa may be removed.

Accordingly, the area of the semiconductor structure SEMSb may be reduced as much as the hatched area of FIG. 11B compared to the semiconductor structure SEMSa, and thus, the chip size of the semiconductor memory device according to an embodiment of the present disclosure may be optimized. The hatched area may be 20% or more of the total area occupied by the semiconductor structure SEMSa.

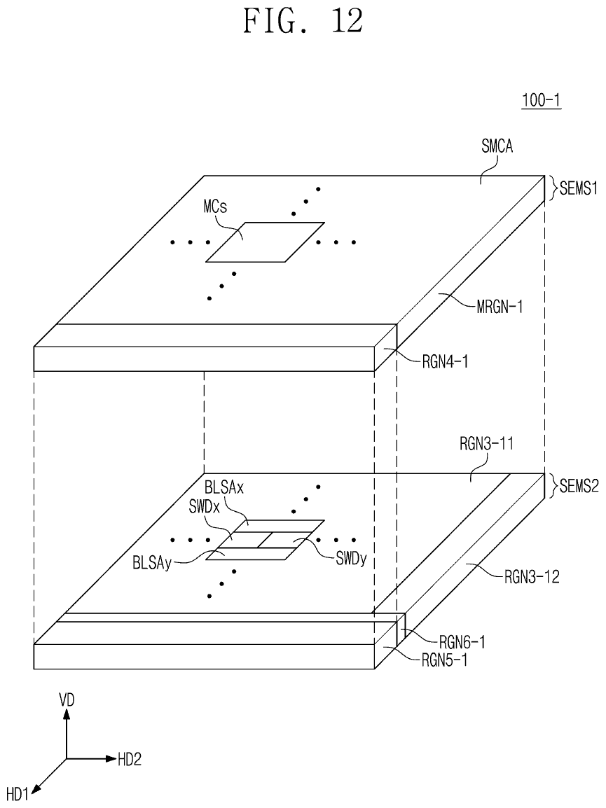

FIG. 12 is a diagram illustrating a portion of the semiconductor memory device of FIG. 1 according to example embodiments. A semiconductor memory device 100-1 of FIG. 12 may correspond to the semiconductor memory device 100 of FIG. 1.

A sub-memory cell array region MRGN-1 and regions RGN3-11, RGN3-12, RGN4-1, RGN5-1, and RGN6-1 are illustrated in FIG. 12.

Referring to FIG. 12, the sub-memory cell array region MRGN-1 may be within the first semiconductor structure SEMS1 and may include one sub-memory cell array SMCA.

The region RGN4-1 may be within the first semiconductor structure SEMS1, may be a portion of the fourth region RGN4 described with reference to the above drawings including FIG. 5A, and may be a region adjacent to the sub-memory cell array region MRGN-1 in the first horizontal direction HD1. In an embodiment, the region RGN4-1 may be a portion of the fourth region RGN4 described with reference to the above drawings including FIGS. 6A, 7A, 8A, and 9.

The regions RGN3-11 and RGN3-12 may be within the second semiconductor structure SEMS2, may be a portion of the third region RGN3 described with reference to the above drawings including FIG. 4A, and may be a region located on the lower side of the sub-memory cell array region MRGN-1. The region RGN3-12 may be a region which is located at the edge of the region RGN3-11 and extends in the first horizontal direction HD1.

The region RGN5-1 may be within the second semiconductor structure SEMS2, may be a portion of the fifth region RGN5 described with reference to the above drawings including FIG. 6A, and may be a region located on the lower side of the region RGN4-1. In an embodiment, the region RGN5-1 may overlap the region RGN4-1 in the vertical direction VD.

The region RGN6-1 may be within the second semiconductor structure SEMS2, may be a portion of the sixth region RGN6 described with reference to the above drawings including FIG. 7A, and may be a region located on the lower side of the sub-memory cell array region MRGN-1. In an embodiment, the region RGN6-1 may overlap a part of the sub-memory cell array region MRGN-1 in the vertical direction VD.

In an embodiment, the sub-memory cell array SMCA may include unit memory cells MCs, and bit line sense amplifiers BLSAx and BLSAy for sensing voltage levels of bit lines or repair bit lines connected to the unit memory cells MCs and sub-word line drivers SWDx and SWDy for driving word lines connected to the unit memory cells MCs may be disposed in the region RGN3-11.

In an embodiment, various control circuits and driving circuits capable of controlling an input/output line driving circuit capable being disposed in the region RGN6-1 or controlling operations of the bit line sense amplifiers BLSAx and BLSAy and the sub-word line drivers SWDx and SWDy may be disposed in the region RGN3-12.

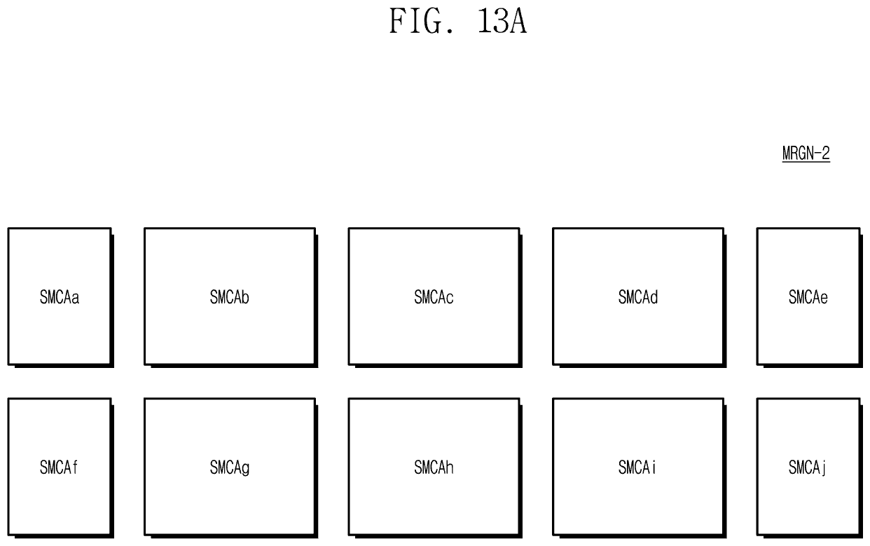

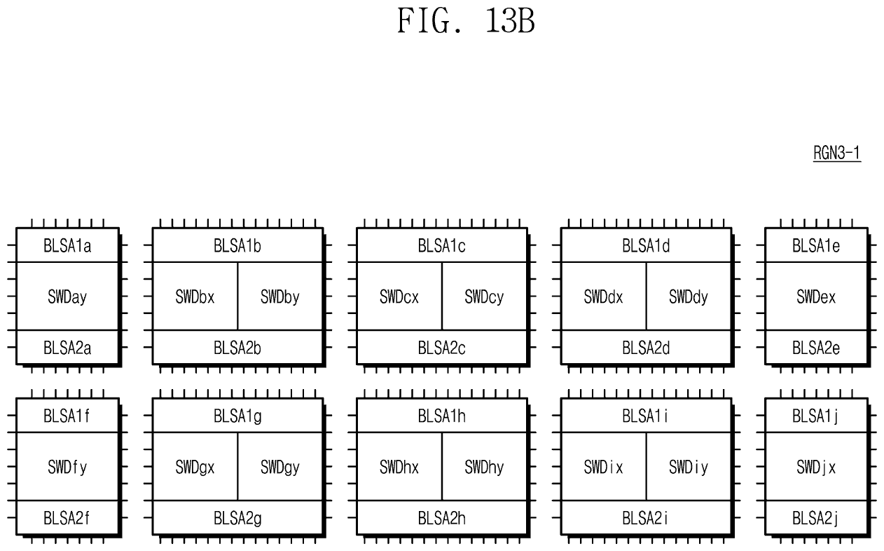

FIG. 13A is a diagram for describing a plurality of sub-memory cell arrays disposed in a memory region of the semiconductor memory device of FIG. 1 according to example embodiments. FIG. 13B is a diagram for describing a peripheral circuits disposed on lower sides of the plurality of sub-memory cell arrays of FIG. 13A according to example embodiments.

Referring to FIG. 13A, a memory region MRGN-2 may include a plurality of sub-memory cell arrays SMCAa, SMAb, SMCAc, SMCAd, SMCAe, SMCAf, SMCAg, SMCAh, SMCAi, and SMCAj. Each of the plurality of sub-memory cell arrays SMCAa to SMCAj may include a plurality of memory cells connected to a plurality of word lines and a plurality of bit lines and may correspond to the sub-memory cell array SMCAx described with reference to FIG. 2.

The sub-memory cell arrays SMCAa to SMCAe may be disposed at the first row, and the sub-memory cell arrays SMCAf to SMCAj may be disposed at the second row.

Referring to FIG. 13B, peripheral circuits corresponding to the plurality of sub-memory cell arrays SMCAa to SMCAj may be disposed in the region RGN3-1. For example, bit line sense amplifiers BLSA1a and BLSA2a and a sub-word line driver SWDay corresponding to the sub-memory cell array SMCAa may be disposed in the region RGN3-1. Bit line sense amplifiers BLSA1b and BLSA2b and sub-word line drivers SWDay and SWDby corresponding to the sub-memory cell array SMCAb may be disposed in the region RGN3-1. Bit line sense amplifiers BLSA1c and BLSA2c and sub-word line drivers SWDcx and SWDcy corresponding to the sub-memory cell array SMCAc may be disposed in the region RGN3-1. As in the above description, bit line sense amplifiers and sub-word line drivers corresponding to the remaining sub-memory cell arrays SMCAd to SMCAj may be disposed in the region RGN3-1.

The sub-memory cell arrays SMAa to SMAj and the peripheral circuits of FIGS. 13A and 13B may be in the shape of a matrix with two rows and five columns, but this is only an example. The number of rows of sub-memory cell arrays or the number of columns of sub-memory cell arrays may increase or decrease.

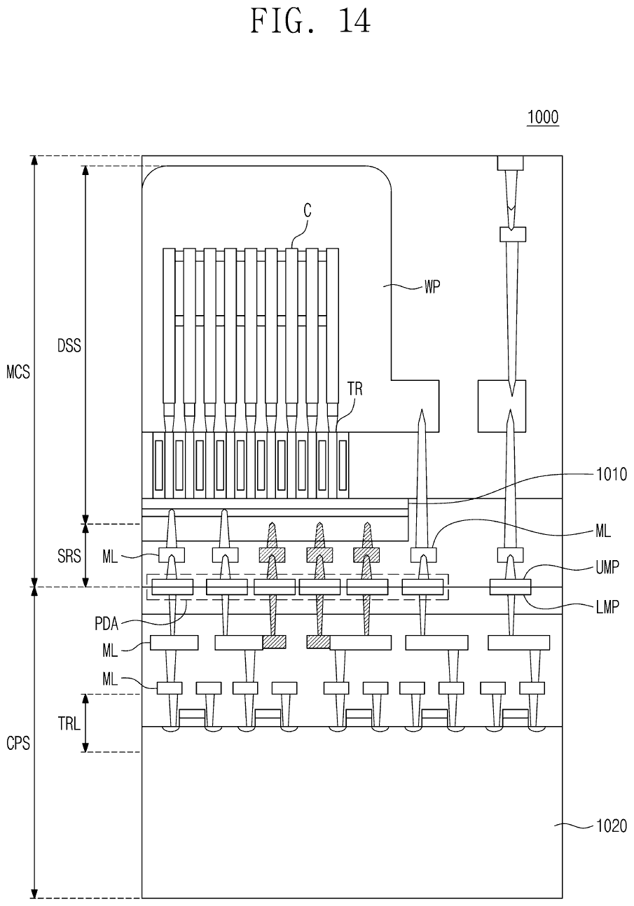

FIG. 14 is a diagram illustrating a semiconductor memory device according to embodiments of the present disclosure.

Referring to FIG. 14, a semiconductor memory device 1000 may include a memory cell array structure MCS and a core-peripheral circuit structure CPS.

The memory cell array structure MCS may be formed on a first substrate 1010. The memory cell array structure MCS may include a data storage structure DSS and a signal routing structure SRS. The data storage structure DSS may include a plurality of memory cells each including a capacitor “C” and a cell transistor TR, a plurality of bit lines, and a plurality of word lines. The signal routing structure SRS may include a plurality of upper metal pads UMP and a plurality of metal lines ML. The plurality of metal lines ML may provide the electrical connection between the plurality of upper metal pads UMP and the data storage structure DSS. For example, the plurality of metal lines ML may provide the electrical connection of some of the plurality of upper metal pads UMP and the bit lines or the electrical connection of some of the plurality of upper metal pads UMP and the word lines.

The core-peripheral circuit structure CPS may be formed on a second substrate 1020. The core-peripheral circuit structure CPS may include a transistor layer TRL. A plurality of transistors for driving the memory cell array structure MCS may be disposed on the transistor layer TRL. Some of the plurality of transistors disposed in the transistor layer TRL may constitute bit line sense amplifiers. Others of the plurality of transistors disposed in the transistor layer TRL may constitute sub-word line drivers. The others of the plurality of transistors disposed in the transistor layer TRL may constitute any other peripheral circuits for the operation of the semiconductor memory device 1000.

The plurality of upper metal pads UMP and a plurality of lower metal pads LMP may be disposed at locations corresponding to each other and provide the electrical connection between each component formed in the first substrate 1010 and each component formed in the second substrate 1020. The plurality of upper metal pads UMP and the plurality of lower metal pads LMP may constitute a pad array PDA.

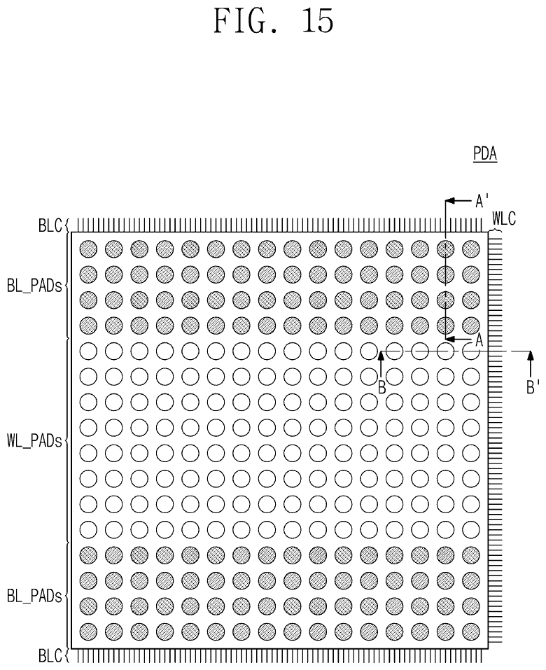

FIG. 15 is a plan view illustrating a pad array included in the semiconductor memory device of FIG. 14 according to example embodiments.

Referring to FIG. 15, the pad array PDA may include a plurality of bit line pads BL_PADs and a plurality of word line pads WL_PADs. The pad array PDA may include one of the plurality of upper metal pads UMP or the plurality of lower metal pads LMP illustrated in FIG. 14. Each of a plurality of circles in the pad array PDA may indicate the plurality of upper metal pads UMP of the semiconductor memory device of FIG. 14.

The plurality of bit line pads BL_PADs may be distributed and disposed with the plurality of word line pads WL_PADs interposed therebetween. The plurality of bit line pads BL_PADs may be electrically connected to bit line connection regions BLC through one or more metal layers. The bit line pads BL_PADs disposed on one side of the plurality of word line pads WL_PADs may be routed to the bit line connection regions BLC adjacent thereto, and the bit line pads BL_PADs disposed on the other side of the plurality of word line pads WL_PADs may be routed to the bit line connection regions BLC adjacent thereto.

The plurality word line pads WL_PADs may be electrically connected to a word line connection region WLC through one or more metal layers.

The bit line connection region BLC may provide the electrical connection between the plurality of bit line pads BL_PADs and bit lines included in a memory cell array. The word line connection region WLC may provide the electrical connection between the plurality of word line pads WL_PADs and word lines included in the memory cell array.

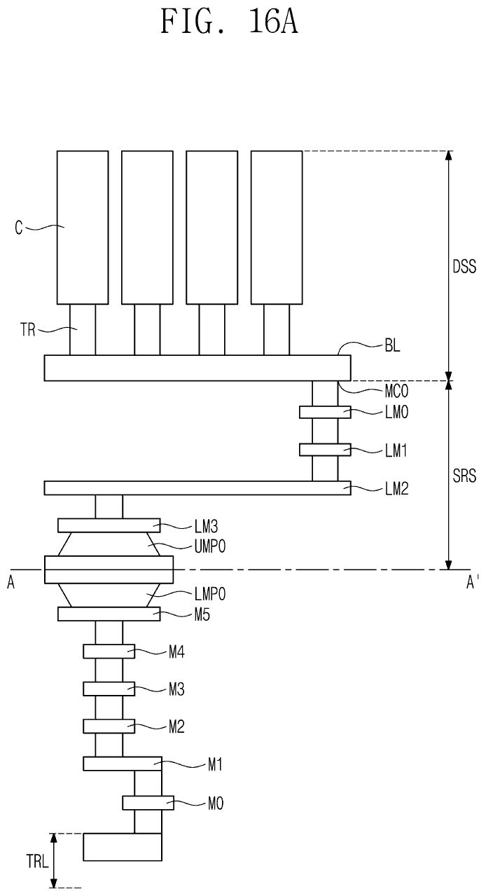

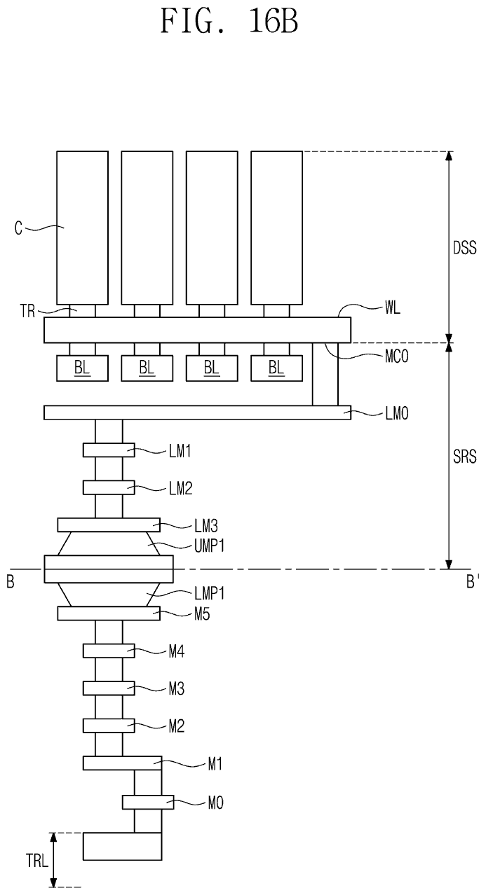

FIG. 16A is a cross-sectional view of the semiconductor memory device of FIG. 14 taken along line A-A′ of FIG. 15 according to example embodiments.

Referring to FIG. 16A, the bit line sense amplifiers disposed in the transistor layer TRL may be electrically connected to the bit line BL.

For convenience of description, the remaining components (e.g., neighboring metal pads) other than components providing the electrical connection between the bit line sense amplifiers disposed in the transistor layer TRL and the bit line BL will be omitted in FIG. 16A. The bit line sense amplifiers disposed in the transistor layer TRL may be electrically connected to a lower metal pad LMP0 through metal layers M0, M1, M2, M3, M4, and M5. The lower metal pad LMP0 may physically and electrically contact an upper metal pad UMP0. The upper metal pad UMP0 may be electrically connected to a plurality of metal lines LM3, LM2, LM1, and LM0. The metal line LM0 may be connected to the bit line BL through a metal contact MC0. The metal contact MC0 may be formed in the bit line connection region BLC of FIG. 15. The change in a potential of the bit line BL by the capacitor “C” and the cell transistor TR is applied (or transferred) to the transistor layer TRL through the plurality of metal lines LM0 to LM3, the upper metal pad UMP0, the lower metal pad LMP0, and the plurality of metal layers M0 to M5. The bit line sense amplifiers disposed in the transistor layer TRL may sense data stored in the capacitor “C” by amplifying the change in the potential of the bit line BL. The data storage structure DSS may include a plurality of capacitors “C”, cell transistors TR, and a plurality of bit lines BL. The signal routing structure SRS may include the plurality of metal lines LM0 to LM3 and the upper metal pad UMP0.

FIG. 16B is a cross-sectional view of the semiconductor memory device of FIG. 14 taken along line B-B′ of FIG. 15 according to example embodiments.

Referring to FIG. 16B, the sub-word line driver disposed in the transistor layer TLR may be electrically connected to the word line WL.

For convenience of description, the remaining components (e.g., neighboring metal pads) other than components providing the electrical connection between the sub-word line driver disposed in the transistor layer TRL and the word line WL will be omitted in FIG. 16B. The sub-word line driver disposed in the transistor layer TRL may be electrically connected to a lower metal pad LMP1 through the metal layers M0, M1, M2, M3, M4, and M5. The lower metal pad LMP1 may physically and electrically contact an upper metal pad UMP1. The upper metal pad UMP1 may be electrically connected to the plurality of metal lines LM3, LM2, LM1, and LM0. The metal line LM0 may be connected to the word line WL through the metal contact MC0. The metal contact MC0 may be formed in the word line connection region WLC of FIG. 15. A word line driving voltage which the sub-word line driver outputs may be applied to the word line WL through the plurality of metal layers M0 to M5, the lower metal pad LMP1, the upper metal pad UMP1, the plurality of metal lines LM0 to LM3, and the metal contact MC0. The cell transistor TR may be switched by the word line driving voltage applied to the word line WL, and thus, the bit line BL and the capacitor “C” may be electrically connected. The data storage structure DSS may include the plurality of capacitors “C”, the cell transistors TR, the plurality of bit lines BL, and a plurality of word lines WL. The signal routing structure SRS may include the plurality of metal lines LM0 to LM3 and the upper metal pad UMP1.

As described above, a semiconductor memory device according to embodiments of the present disclosure may include peripheral circuits disposed in an upper middle region between one memory cell array region and another memory cell array region. In the semiconductor memory device with the COP structure, the upper middle region may be a region in a first semiconductor structure where a memory cell array is formed, and peripheral circuits having a characteristic of a given level or more from among all peripheral circuits of the semiconductor memory device may be only disposed in the upper middle region in consideration of the process of manufacturing the memory cell array or an operation of the semiconductor memory device. As all the peripheral circuits of the semiconductor memory device are appropriately distributed and disposed in the upper middle region and the lower middle region, the chip size of the semiconductor memory device may be optimized.

While the present disclosure has been described with reference to embodiments thereof, it will be apparent to those of ordinary skill in the art that various changes and modifications may be made thereto without departing from the spirit and scope of the present invention as set forth in the following claims.

What is claimed is:

1. A semiconductor memory device with a cell over periphery (COP) structure, the semiconductor memory device comprising:
a first semiconductor structure; and
a second semiconductor structure disposed on a lower side of the first semiconductor structure,
wherein the first semiconductor structure includes:
a memory region and a first region;
a memory cell array disposed in the memory region and including vertical channel transistors (VCTs); and
first peripheral circuits disposed in the first region and including VCTs or horizontal channel transistors (HCTs), and
wherein the second semiconductor structure includes:
a second region and a third region;
second peripheral circuits disposed in the second region, which is on a lower side of the first region, and including HCTs; and
third peripheral circuits disposed in the third region, which is on a lower side of the memory region, and including HCTs.

2. The semiconductor memory device of claim 1, wherein each of the first peripheral circuits has heat resistance under a first condition associated with a process of manufacturing the semiconductor memory device.

3. The semiconductor memory device of claim 2, wherein the memory cell array includes a plurality of first sub-memory cell arrays and a plurality of second sub-memory cell arrays,
wherein the plurality of first sub-memory cell arrays are disposed adjacent to each other at a first row in the memory cell array,
wherein the plurality of second sub-memory cell arrays are disposed adjacent to each other at a second row in the memory cell array, and
wherein the first peripheral circuits are disposed between the plurality of first sub-memory cell arrays and the plurality of second sub-memory cell arrays.

4. The semiconductor memory device of claim 2, wherein the first peripheral circuits include at least one of a mode register, a refresh controller, a row hammer handler, and a power supply circuit.

5. The semiconductor memory device of claim 4, wherein the second peripheral circuits include at least one of a command decoder, a data input/output buffer, an on-die termination circuit, and an equalizer circuit.

6. The semiconductor memory device of claim 5, wherein the third peripheral circuits include at least one of bit line sense amplifiers, sub-word line drivers, a row decoder, and a column decoder.

7. The semiconductor memory device of claim 6, wherein the memory region and the first region are sequentially disposed along a first direction in the first semiconductor structure, and
wherein the third region and the second region are sequentially disposed along the first direction in the second semiconductor structure.

8. The semiconductor memory device of claim 1, wherein the first semiconductor structure further includes:
a repair control circuit disposed in a fourth region in the first semiconductor structure.

9. The semiconductor memory device of claim 8, wherein the memory region, the fourth region, and the first region are sequentially disposed along a first direction or a direction facing away from the first direction, in the first semiconductor structure.

10. The semiconductor memory device of claim 8, wherein the second semiconductor structure further includes:
an error correction code (ECC) circuit disposed in a fifth region which is in the second semiconductor structure and is on a lower side of the fourth region.

11. The semiconductor memory device of claim 10, wherein the third region, the fifth region, and the second region are sequentially disposed along a first direction or a direction facing away from the first direction, in the second semiconductor structure.

12. The semiconductor memory device of claim 10, wherein the second semiconductor structure further includes:
input/output line driving circuits disposed in a sixth region which is in the second semiconductor structure, is on a lower side of the memory region, and is between the third region and the fifth region.

13. The semiconductor memory device of claim 12, wherein the third region, the sixth region, the fifth region, and the second region are sequentially disposed along a first direction or a direction facing away from the first direction, in the second semiconductor structure.

14. The semiconductor memory device of claim 12, wherein the second semiconductor structure further includes:
an electrostatic protection circuit disposed in a seventh region which is in the second semiconductor structure, is on a lower side of the first region, and is between the second region and the fifth region.

15. The semiconductor memory device of claim 14, wherein the third region, the sixth region, the fifth region, the seventh region, and the second region are sequentially disposed along a first direction or a direction facing away from the first direction, in the second semiconductor structure.

16. A semiconductor memory device with a cell over periphery (COP) structure, the semiconductor memory device comprising:
a first semiconductor structure; and
a second semiconductor structure disposed on a lower side of the first semiconductor structure,
wherein the first semiconductor structure includes:
a memory region and a first region;
a memory cell array including a plurality of first and second sub-memory cell arrays disposed in the memory region and implemented by using vertical channel transistors (VCTs); and
first peripheral circuits disposed in the first region and implemented by using VCTs or horizontal channel transistors (HCTs), and
wherein the second semiconductor structure includes:
a second region and a third region;
second peripheral circuits disposed in the second region, which is on a lower side of the first region; and
third peripheral circuits disposed in the third region, which is on a lower side of the memory region.

17. The semiconductor memory device of claim 16, wherein each of the first peripheral circuits has heat resistance under a first condition associated with a process of manufacturing the semiconductor memory device.

18. The semiconductor memory device of claim 17, wherein the plurality of first sub-memory arrays are disposed adjacent to each other at a first row in the memory region,
wherein the plurality of second sub-memory arrays are disposed adjacent to each other at a second row in the memory region, and
wherein the first peripheral circuits are disposed between the plurality of first sub-memory cell arrays and the plurality of second sub-memory cell arrays.

19. The semiconductor memory device of claim 18, wherein the first peripheral circuits include a refresh controller.

20. A semiconductor memory device with a cell over periphery (COP) structure, the semiconductor memory device comprising:
a first semiconductor structure; and
a second semiconductor structure disposed on a lower side of the first semiconductor structure,
wherein the first semiconductor structure includes:
a memory region and a first region;
a memory cell array disposed in the memory region and including vertical channel transistors (VCTs); and
first peripheral circuits disposed in the first region, including VCTs or horizontal channel transistors, and having first timing margins associated with an operation of the semiconductor memory device,
wherein the second semiconductor structure includes:
a second region;
second peripheral circuits disposed in the second region, which is on a lower side of the first region, and having second timing margins associated with an operation of the semiconductor memory device, and
wherein the first timing margins are greater than the second timing margins.
